(19) United States
(12) Patent Application Publication
(10) Pub. No.: US 2025/0327757 A1
(43) Pub. Date: Oct. 23, 2025

(54) SHEET FIXING APPARATUS AND METHOD OF MANUFACTURING COMBINATION OF WORKPIECE AND SHEET FIXED THERETO

(71) Applicant: DISCO CORPORATION, Tokyo (JP)

(72) Inventors: Yuta TANIYAMA, Tokyo (JP); Yoshinori KAKINUMA, Tokyo (JP); Mitsuru IKUSHIMA, Tokyo (JP); Yoshikuni MIGIYAMA, Tokyo (JP); Fuki SAWASHIMA, Tokyo (JP); Takashi MORI, Tokyo (JP)

(21) Appl. No.: 19/175,185

(22) Filed: Apr. 10, 2025

(30) Foreign Application Priority Data
Apr. 23, 2024 (JP) 2024-069674

(51) Int. Cl. G01N 21/95; G01N 21/88; H01L 21/02; H01L 21/66; H01L 21/677; H01L 21/68

(52) U.S. Cl. CPC G01N 21/9501; G01N 21/8851; H01L 21/02096; H01L 21/6773; H01L 21/67736; H01L 21/68; H01L 22/12; G01N 2021/8858

(57) ABSTRACT

A sheet fixing apparatus includes an image capturing unit having a first camera for capturing images of a target surface of a workpiece before a sheet is fixed to the target surface and a controller for controlling the image capturing unit. The controller determines whether the foreign matter is attached to the target surface or not on the basis of a first image captured of the target surface by the first camera by controlling the image capturing unit to capture the first image before the sheet is fixed to the target surface.

### BACKGROUND OF THE INVENTION

### Field of the Invention

The present invention relates to a sheet fixing apparatus for fixing to a target surface of a workpiece a sheet that is commensurate in shape with the target surface and a method of manufacturing a combination of a workpiece and a sheet fixed to a target surface of the workpiece.

### Description of the Related Art

Chips including devices such as integrated circuits (ICs), for example, are indispensable elements in various electronic appliances including cellular phones and personal computers, for example. Such chips are manufactured from a wafer having a plurality of devices on its face side by thinning down the wafer and then dividing the wafer into a plurality of pieces including the respective devices as chips.

The wafer is thinned down by a grinding apparatus that grinds a reverse side of the wafer, for example. The wafer is divided into the chips by a cutting apparatus or a laser processing apparatus that severs the wafer along boundaries between the devices on the wafer, for example.

When the wafer is thinned down by the grinding apparatus, the face side of the wafer tends to be pressed strongly, possibly causing damage to the devices. When the wafer is divided by the cutting apparatus or the laser processing apparatus, the chips fabricated from the wafer are liable to be separated and scattered and hence to become difficult to handle.

In view of these shortcomings, it has been general practice to fix a sheet to a wafer using a sheet fixing apparatus (see, for example, JP 2016-8104A). The sheet fixing apparatus reels out a desired length of sheet from a stock roll of sheet, cuts off the length of sheet, and fixes the severed individual sheet to a wafer.

### SUMMARY OF THE INVENTION

If foreign matter such as minute dust particles is attached to the wafer, then the sheet may be fixed to the wafer with the foreign matter sandwiched between the sheet and the wafer. When the wafer is subsequently processed, the sandwiched foreign matter is liable to develop large local stresses, tending to damage the wafer.

In view of the above drawbacks, it is an object of the present invention to provide a sheet fixing apparatus that is capable of preventing a sheet from being fixed to a target surface of a workpiece such as a wafer with foreign matter being attached to the target surface.

In accordance with an aspect of the present invention, there is provided a sheet fixing apparatus for fixing to a target surface of a workpiece a sheet that is commensurate in shape with the target surface. The sheet fixing apparatus includes an image capturing unit having a first camera for capturing images of the target surface before the sheet is fixed thereto, and a controller for controlling the image capturing unit, in which the controller determines whether foreign matter is attached to the target surface or not on the basis of a first image captured of the target surface by the first camera by controlling the image capturing unit to capture the first image before the sheet is fixed to the target surface. In accordance with another aspect of the present invention, there is provided a method of manufacturing a combination of a workpiece and a sheet fixed to a target surface of the workpiece, the sheet being commensurate in shape with the target surface, including fixing the sheet to the workpiece after it has been determined that no foreign matter is attached to the target surface on the basis of a first image captured of the target surface.

Preferably, the sheet fixing apparatus further includes a foreign matter removing unit for removing foreign matter from the target surface, in which the controller controls the foreign matter removing unit to remove foreign matter from the target surface if the controller determines that the foreign matter is attached to the target surface.

In the sheet fixing apparatus, preferably, the image capturing unit further has a second camera for capturing images of the sheet after the sheet has been fixed to the target surface, and the controller determines whether foreign matter is attached to the sheet or not on the basis of a second image captured of the sheet by the second camera by controlling the image capturing unit to capture the second image after the sheet has been fixed to the target surface. Preferably, the sheet fixing apparatus further includes a foreign matter removing unit for removing foreign matter from the target surface and/or the sheet, in which the controller controls the foreign matter removing unit to remove foreign matter from the target surface if the controller determines that the foreign matter is attached to the target surface, and controls the foreign matter removing unit to remove foreign matter from the sheet if the controller determines that the foreign matter is attached to the sheet.

Alternatively, preferably, in the sheet fixing apparatus, the first camera is capable of capturing images of the sheet after the sheet has been fixed to the target surface, and the controller determines whether foreign matter is attached to the sheet or not on the basis of a second image captured of the sheet by the first camera by controlling the image capturing unit to capture the second image after the sheet has been fixed to the target surface. Preferably, the sheet fixing apparatus further includes a foreign matter removing unit for removing foreign matter from the target surface and/or the sheet, in which the controller controls the foreign matter removing unit to remove foreign matter from the target surface if the controller determines that the foreign matter is attached to the target surface, and controls the foreign matter removing unit to remove foreign matter from the sheet if the controller determines that the foreign matter is attached to the sheet.

In the sheet fixing apparatus, preferably, the workpiece includes a wafer having a notch or orientation flat defined in an outer edge thereof, and the controller specifies the position of the notch or orientation flat on the basis of a third image captured of the target surface by the first camera by controlling the image capturing unit to capture the third image before the sheet is fixed to the target surface while the workpiece is being irradiated with light applied to a side of the workpiece that is opposite the target surface. Preferably, the sheet fixing apparatus further includes a cassette table supporting thereon a cassette with the workpiece housed therein and an unloading and loading robot for unloading the workpiece from the cassette supported on the cassette table before the sheet is attached to the target surface and/or loading the workpiece into the cassette supported on the cassette table after the sheet has been attached to the target surface, the unloading and loading robot including a holding unit for holding the workpiece and a light emitter for irradiating the workpiece held by the holding unit with light, in which the controller controls the image capturing unit to capture the third image of the target surface before the sheet is fixed to the target surface while controlling the unloading and loading robot to cause the holding unit to hold the workpiece with the target surface being exposed and to cause the light emitter to irradiate the workpiece with light applied to the side of the workpiece that is opposite the target surface.

Moreover, preferably the sheet fixing apparatus further includes a preparing unit for preparing an individual sheet including a to-be-fixed region that is of a shape commensurate with the target surface and an excess region surrounding the to-be-fixed region, a fixing unit for fixing the to-be-fixed region of the individual sheet prepared by the preparing unit to the target surface of the workpiece, and a removing unit for removing the excess region from the individual sheet after the to-be-fixed region has been fixed to the target surface by the fixing unit, the fixing unit including a first holding unit for holding the workpiece, a second holding unit for holding the individual sheet, and a pressing unit for pressing the to-be-fixed region of the individual sheet against the target surface of the workpiece, in which the controller controls the fixing unit to cause the pressing unit to press the to-be-fixed region against the target surface while the first holding unit is holding the workpiece with the target surface being exposed and the second holding unit is holding the individual sheet with the to-be-fixed region being exposed and facing the target surface.

In the sheet fixing apparatus, preferably, the pressing unit includes a roller positioned to grip the individual sheet held by the second holding unit in coaction with the workpiece held by the first holding unit, and the controller controls the pressing unit to cause the roller to roll, thereby pressing the to-be-fixed region against the target surface. Moreover, preferably, in the sheet fixing apparatus, the fixing unit further includes a depressurizing unit for depressurizing a space to a pressure lower than the atmospheric pressure when the to-be-fixed region is fixed to the target surface in the space, the depressurizing unit includes a chamber for accommodating therein the first holding unit for holding the workpiece, the second holding unit for holding the individual sheet, and the roller, and a pump for depressurizing an internal space in the chamber, and the controller controls the pressing unit and the depressurizing unit to press the to-be-fixed region against the target surface while the pump is depressurizing the internal space in the chamber.

In addition, preferably, the sheet fixing apparatus further includes a housing that houses therein the preparing unit, the fixing unit, and the removing unit, a fan for developing a downflow of air in the housing, and a counter for counting fine particles in the housing, in which the controller controls the fan to change operating conditions depending on the number of fine particles counted by the counter.

According to the present invention, the controller determines whether the foreign matter is attached to the target surface or not before the sheet is fixed to the target surface. Therefore, it is possible to prevent the sheet from being fixed to the target surface of the workpiece while the foreign matter is attached to the target surface.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view schematically illustrating a workpiece by way of example;

FIG. 2 is a block diagram schematically illustrating a sheet fixing apparatus according to an embodiment of the present invention;

FIG. 3 is a perspective view schematically illustrating a cassette table that supports thereon a cassette housing workpieces therein;

FIG. 4 is a perspective view schematically illustrating an unloading and loading robot;

FIG. 5 is a perspective view schematically illustrating an image capturing unit;

FIG. 6 is a side elevational view schematically illustrating the manner in which the image capturing unit captures an image of a workpiece;

FIG. 7 is a perspective view schematically illustrating a foreign matter removing unit;

FIG. 8 is a perspective view schematically illustrating a preparing unit;

FIG. 9 is a perspective view schematically illustrating a stock roll of sheet;

FIG. 10 is a side elevational view, partly in cross section, schematically illustrating the manner in which some components of the preparing unit operate to blank out a to-be-peeled-off region of a protective sheet;

FIG. 11A is a side elevational view, partly in cross section, schematically illustrating the manner in which some components of the preparing unit operate to peel off the to-be-peeled-off region of the protective sheet from the individual sheet;

FIG. 11B is a side elevational view, partly in cross section, schematically illustrating the manner in which some components of the preparing unit operate to peel off the to-be-peeled-off region of the protective sheet from the individual sheet;

FIG. 12A is a side elevational view, partly in cross section, schematically illustrating the manner in which some components of the preparing unit operate to peel off the to-be-peeled-off region of the protective sheet from the individual sheet;

FIG. 12B is a side elevational view, partly in cross section, schematically illustrating the manner in which some components of the preparing unit operate to peel off the to-be-peeled-off region of the protective sheet from the individual sheet;

FIG. 13A is a side elevational view, partly in cross section, schematically illustrating the manner in which some components of the preparing unit operate to peel off the to-be-peeled-off region of the protective sheet from the individual sheet;

FIG. 13B is a side elevational view, partly in cross section, schematically illustrating the manner in which some components of the preparing unit operate to peel off the to-be-peeled-off region of the protective sheet from the individual sheet;

FIG. 14 is a perspective view schematically illustrating a fixing unit;

FIG. 15 is a perspective view schematically illustrating a removing unit;

FIG. 16 is a perspective view schematically illustrating an appearance of the sheet fixing apparatus;

FIG. 17A is a block diagram schematically illustrating the hardware makeup of a controller of the sheet fixing apparatus; and

FIG. 17B is a block diagram schematically illustrating functions performed by the controller.

### DETAILED DESCRIPTION OF THE PREFERRED EMBODIMENTS

### <1. Workpiece>

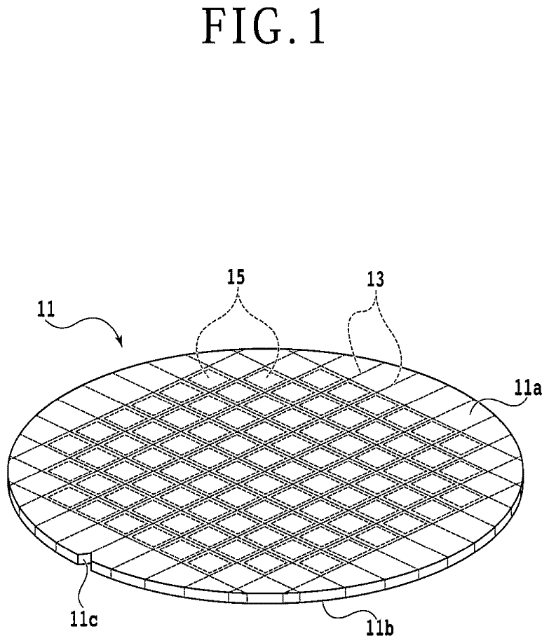

FIG. 1 schematically illustrates a workpiece 11 in perspective. As illustrated in FIG. 1, the workpiece 11 includes, for example, a disk-shaped wafer made of a semiconductor material such as silicon (Si) and having a circular face side 11a and a circular reverse side 11b opposite the circular face side 11a.

The workpiece 11 has a notch 11c defined in an outer edge thereof as a mark indicating the crystal orientation of the semiconductor material. The workpiece 11 has a grid of areas demarcated on the face side 11a by a plurality of projected dicing lines 13 established in the workpiece 11. Devices 15 such as ICs are constructed respectively in the demarcated areas.

The workpiece 11 is not limited to any particular materials, shapes, structures, and sizes, for example. The material, for example, of the workpiece 11 may be ceramic, resin, or metal. Moreover, the workpiece 11 may have an orientation flat defined in the outer edge thereof rather than the notch 11c.

### <2. Sheet Fixing Apparatus>

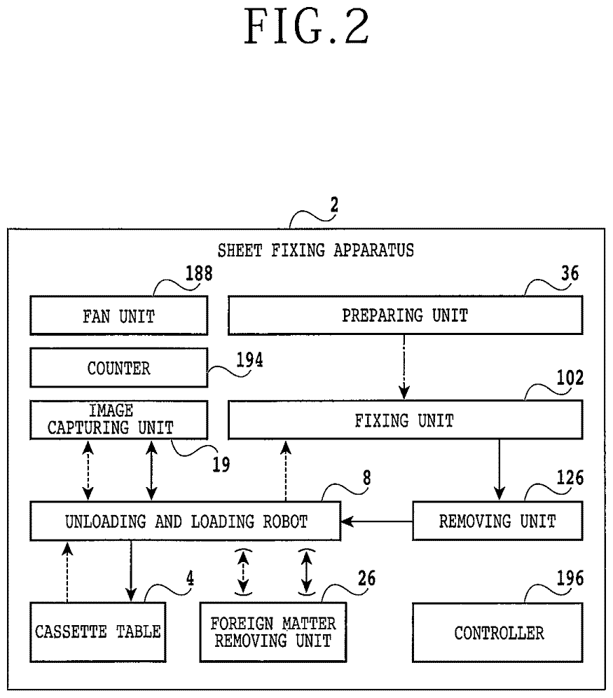

FIG. 2 schematically illustrates, in block form, a sheet fixing apparatus 2 for fixing a sheet to the workpiece 11. In the sheet fixing apparatus 2 illustrated FIG. 2, the workpiece 11 moves along paths indicated by broken-line arrows, a sheet moves along a path indicated by a dot-and-dash-line arrow, and a combination of the workpiece 11 and the sheet fixed thereto moves along paths indicated by solid-line arrows.

### <(1) Cassette Table>

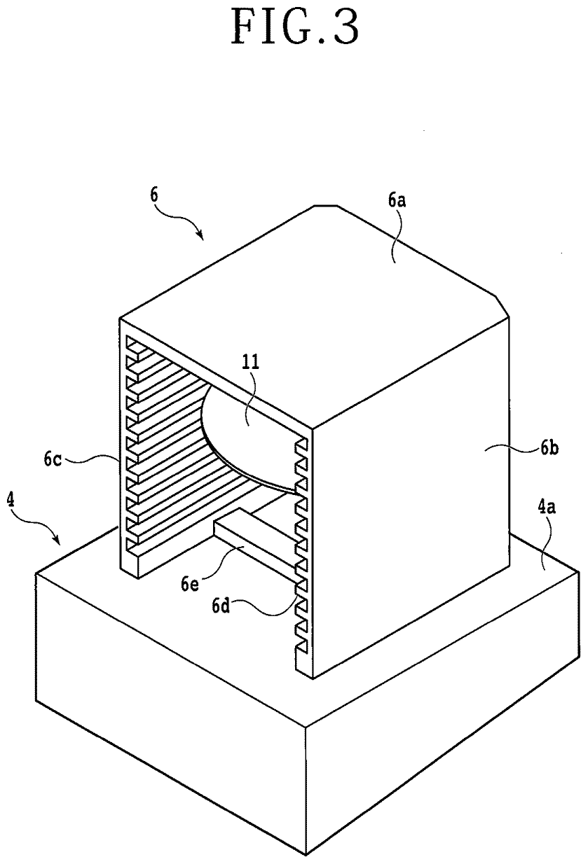

The sheet fixing apparatus 2 includes a cassette table 4 for supporting thereon a cassette that houses workpieces 11. FIG. 3 schematically illustrates, in perspective, the cassette table 4 that supports thereon the cassette, denoted by 6, housing workpieces 11 therein. The cassette table 4 has a rectangular upper surface 4a that lies essentially horizontally, i.e., perpendicularly to vertical directions, with the cassette 6 placed on the upper surface 4a.

The cassette 6 has a top plate 6a shaped as a flat rectangular plate. The top plate 6a has four corners including a pair of two adjacent rear corners beveled and a pair of other two adjacent front corners not beveled but remaining right-angled. The cassette 6 has a rear plate, not depicted, extending vertically perpendicularly to the top plate 6a and having an upper end secured to the lower side of a rear end of the top plate 6a that extends between the beveled rear corners thereof.

The cassette 6 further has two side plates 6b and 6c extending vertically that have respective upper ends secured to respective two side ends, i.e., left and right side ends, of the top plate 6a that are positioned between the beveled rear corners and the non-beveled front corners of the top plate 6a. The cassette 6 is free of a front plate below a front end of the top plate 6a that is positioned between the non-beveled front corners of the top plate 6a. In other words, the cassette 6 has an open front side below the front end of the top plate 6a.

Each of the side plates 6b and 6c have a plurality of slots 6d defined in an inner side surface thereof at equally vertically spaced intervals and extending horizontally between the front and rear ends of the cassette 6. Each of the slots 6d in the inner side surface of the side plate 6b horizontally faces one of the slots 6d in the inner side surface of the side plate 6c.

Each of the slots 6d is of an essentially rectangular cross-sectional shape. Stated otherwise, each of the slots 6d is defined by a pair of upper and lower side surfaces lying horizontally and spaced vertically from each other and a bottom surface extending vertically between ends of the side surfaces. The slots 6d in the side plates 6b and 6c jointly provide a vertical array of storage spaces each for storing a workpiece 11 therein. The workpiece 11 that is placed in each of the storage spaces has its outer edge placed on the side surfaces of the slots 6d remote from the top plate 6a. In other words, the workpiece 11 in each storage space is supported on the side surfaces of the slots 6d remote from the top plate 6a.

The cassette 6 may have as many slots 6d defined in the inner side surfaces of the side plates 6b and 6c as desired. For example, the cassette 6 may have as many slots 6d as required to provide storage spaces for storing workpieces 11 of one log, i.e., about 25 workpieces 11. The side plates 6b and 6c have respective lower portions interconnected by a slender joint bar 6e extending perpendicularly to the side plates 6b and 6c.

### <(2) Unloading and Loading Robot>

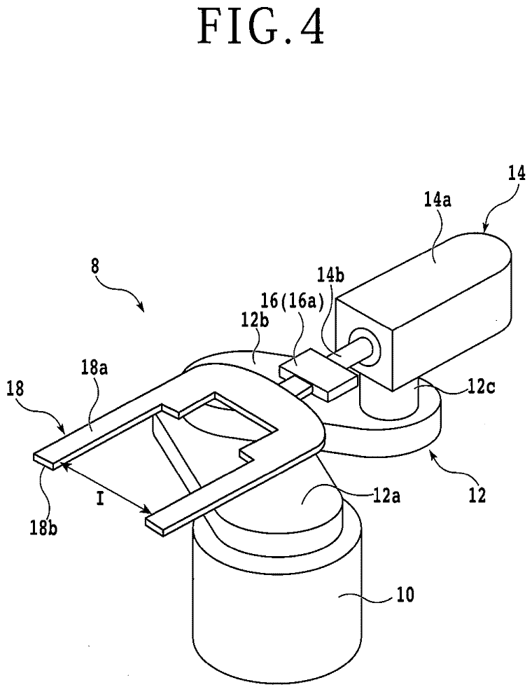

The workpieces 11 stored in the cassette 6 are unloaded one by one therefrom by an unloading and loading robot 8 (see FIG. 2). FIG. 4 schematically illustrates the unloading and loading robot 8 in perspective. As illustrated in FIG. 4, the unloading and loading robot 8 has a cylindrical first drive unit 10 extending vertically. The first drive unit 10 includes, for example, an actuator, not depicted, such as an air cylinder for selectively raising and lowering a rod.

The first drive unit 10 has an opening defined in its upper end through which the rod extends. The rod has an upper end to which a delivery arm 12 is coupled, so that the delivery arm 12 is vertically movable. Specifically, when the first drive unit 10 is actuated, it lifts or lowers the rod, moving the delivery arm 12 vertically, i.e., lifting or lowering the delivery arm 12.

The delivery arm 12 has a plurality of joints. Specifically, the delivery arm 12 includes a plate-shaped first arm 12a extending horizontally. The first arm 12a has an end whose lower side is coupled to the upper end of the rod of the first drive unit 10 for movement and rotation with the rod. The first arm 12a has an opposite end whose upper side is coupled to a lower portion of a first cylindrical joint, not depicted.

The first cylindrical joint has an upper portion coupled to a plate-shaped second arm 12b extending horizontally. The second arm 12b has an end whose lower side is coupled to the upper side of the opposite end of the first arm 12a through the first cylindrical joint for rotation about a vertical axis at the center of the first cylindrical joint. The second arm 12b has an opposite end whose upper side is coupled to a lower end of a second cylindrical joint 12c.

The second cylindrical joint 12c has an upper end coupled to a rotating mechanism 14. The rotating mechanism 14 has a cuboid case 14a extending horizontally and a spindle 14b inserted horizontally into the cuboid case 14a through an opening defined in a vertical end plate on an end of the cuboid case 14a.

The cuboid case 14a has a lower side near the vertical end plate that is coupled to the upper side of the opposite end of the second arm 12b through the second cylindrical joint 12c for rotation about a vertical axis at the center of the second cylindrical joint 12c. The cuboid case 14a houses therein an electric motor, not depicted, coupled to a proximal end of the spindle 14b that is also housed in the cuboid case 14a. When the electric motor is energized, it rotates the spindle 14b about a horizontal central axis thereof.

A light emitter 16 is connected to a distal end of the spindle 14b that is remote from the cuboid case 14a. The light emitter 16 has a plate-shaped case 16a fixed to the distal end of the spindle 14b and a light source, not depicted, such as a light-emitting diode (LED) housed in the case 16a. The case 16a has a vertical side plate remote from the spindle 14b, facing away from the spindle 14b and having an opening defined therein.

When the light source housed in the case 16a is energized, it emits light such as visible light that travels through the opening in the vertical side plate of the case 16a away from the light emitter 16. To the vertical side plate of the case 16a, there is connected a U-shaped holding unit 18 for holding thereon a workpiece 11 with or without a sheet fixed thereto. The holding unit 18 has a proximal end whose central portion is secured to the case 16a, i.e., the vertical side plate thereof remote from the spindle 14b, such that the holding unit 18 is axisymmetric with respect to a straight line aligned with the horizontal central axis of the spindle 14b.

The holding unit 18 is of a bifurcated shape including a pair of fingers that are spaced from each other by a distance I that is smaller than the diameter of the workpieces 11 to be handled by the unloading and loading robot 8, e.g., is equal to the radius of the workpieces 11. The holding unit 18 houses therein a light guide, not depicted, made of a light-transmissive synthetic resin and having an end optically coupled to the opening in the vertical side plate of the case 16a of the light emitter 16. The light guide in the holding unit 18 is coextensive with a surface 18a of the holding unit 18 and is optically coupled therewith. The light emitted from the light emitter 16 is introduced into the light guide in the holding unit 18 and applied to the surface 18a, illuminating the surface 18a that gives off light by way of surface emission.

The holding unit 18 also has another surface 18b opposite the surface 18a. Each of the surfaces 18a, 18b has a plurality of suction holes, not depicted, defined therein. The suction holes defined in the surface 18a are fluidly connectable selectively to a first suction source, not depicted, and a first air supply source, not depicted. The suction holes defined in the surface 18b are fluidly connectable selectively to a second suction source, not depicted, that is different from the first suction source and a second air supply source, not depicted, that is different from the first air supply source.

Each of the first suction source and the second suction source includes an ejector, for example. Each of the first air supply source and the second air supply source includes a tank for storing air, a filter for removing foreign matter contained in the air supplied from the tank, and a regulator for regulating the pressure of the air supplied from the tank, for example.

A target object that is to be delivered by the unloading and loading robot 8, specifically a workpiece 11 with or without a sheet fixed thereto, is placed on the surface 18a of the holding unit 18. When the first suction source is connected to the suction holes defined in the surface 18a and actuated, it develops a negative pressure in the suction holes, thereby generating a suction force in a space near the surface 18a. Therefore, the target object placed on the surface 18a is held under suction on the surface 18a.

Then, while the target object is being placed on the surface 18a, when the first suction source connected to the suction holes defined in the surface 18a is turned off and disconnected from the suction holes and the first air supply source is connected to the suction holes and actuated, the first air supply source supplies air to the suction holes, bringing the atmospheric pressure back in the suction holes. The suction force that has acted on the target object is eliminated, freeing the target object from the surface 18a.

Alternatively, a target object that is to be delivered by the unloading and loading robot 8 is placed on the surface 18b of the holding unit 18. When the second suction source is connected to the suction holes defined in the surface 18b and actuated, it develops a negative pressure in the suction holes, thereby generating a suction force in a space near the surface 18b. Therefore, the target object placed on the surface 18b is held under suction on the surface 18b.

Then, while the target object is being placed on the surface 18b, when the second suction source connected to the suction holes defined in the surface 18b is turned off and disconnected from the suction holes and the first air supply source is connected to the suction holes and actuated, the second air supply source supplies air to the suction holes, bringing the atmospheric pressure back in the suction holes. The suction force that has acted on the target object is eliminated, freeing the target object from the surface 18b.

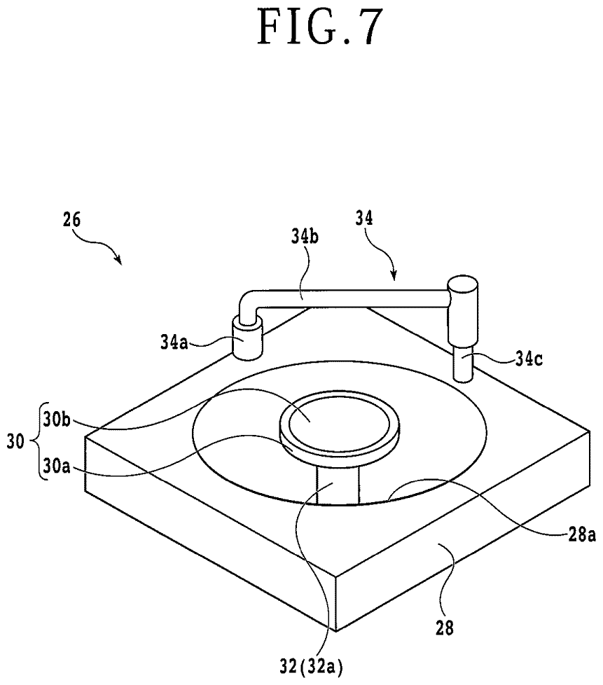

The surface 18a of the holding unit 18 is used to carry a target object before foreign matter is removed from the target object by a foreign matter removing unit 26 (see FIG. 7), for example. The other surface 18b of the holding unit 18 is used to carry a target object after foreign matter has been removed therefrom by the foreign matter removing unit 26. Consequently, the surface 18b that holds the cleaned target object tends to remain relatively clean compared with the surface 18a that holds the delivery target to be cleaned, and is less liable to transfer foreign matter to a target object held thereon.

While a target object is being held on the surface 18a or the surface 18b, when the electric motor housed in the cuboid case 14a of the rotating mechanism 14 is energized, the spindle 14b, the light emitter 16, the holding unit 18, and the target object are rotated about the horizontal central axis of the spindle 14b. Accordingly, the target object held on the surface 18a or the surface 18b can be vertically inverted or turned upside down by rotating the spindle 14b through 1800 with the electric motor.

The unloading and loading robot 8 is coupled to a horizontally moving mechanism, not depicted. The horizontally moving mechanism includes a support plate that supports the unloading and loading robot 8 thereon, a ball screw for moving the support plate horizontally, and an electric motor for rotating a screw shaft of the ball screw about its longitudinal central axis. When the electric motor is energized, it rotates the screw shaft about its longitudinal central axis, causing the support plate and hence the unloading and loading robot 8 to move horizontally.

### <(3) Image Capturing Unit>

The unloading and loading robot 8 delivers the workpiece 11 to an image capturing unit 19 (see FIG. 2) before a sheet is fixed to a target surface, i.e., the face side 11a, of the workpiece 11. The image capturing unit 19 captures an image that can be used to determine whether foreign matter is attached to the face side 11a of the workpiece 11 or not, for example. The image capturing unit 19 may also capture an image for use in grasping the position of the notch 11c or orientation flat in the workpiece 11.

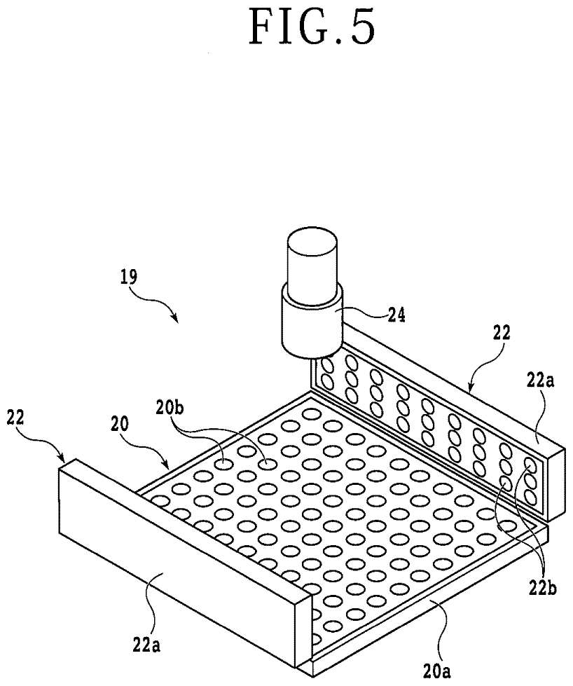

FIG. 5 schematically illustrates the image capturing unit 19 in perspective. As illustrated in FIG. 5, the image capturing unit 19 has a back lighting device 20. The back lighting device 20 includes a horizontal support plate 20a that is of a rectangular shape as viewed in plan and a plurality of light sources, e.g., LEDs, 20b arranged in a matrix on an upper surface of the support plate 20a, each of a circular shape as viewed in plan. When the light sources 20b are energized, they emit light such as visible light upwardly from the back lighting device 20.

The image capturing unit 19 also has a pair of oblique lighting devices 22 disposed on respective opposite sides of the back lighting device 20 and facing each other as viewed in plan. Each of the oblique lighting devices 22 includes a vertical support plate 22a having a length generally equal to the length of the back lighting device 20 and a plurality of light sources, e.g., LEDs, 22b arranged in a matrix on a side surface of the support plate 22a, each of a circular shape as viewed in front. When the light sources 22b are energized, they emit light such as visible light obliquely downwardly from the oblique lighting devices 22 toward the back lighting device 20, for example.

The image capturing unit 19 further has a camera 24 disposed directly above the back lighting device 20 and obliquely upwardly of the oblique lighting devices 22. The camera 24 includes an objective lens and a light detector such as a charge-coupled-device (CCD) image sensor or a complementary-metal-oxide-semiconductor (CMOS) image sensor, for example. The camera 24 is oriented downwardly to capture images below itself.

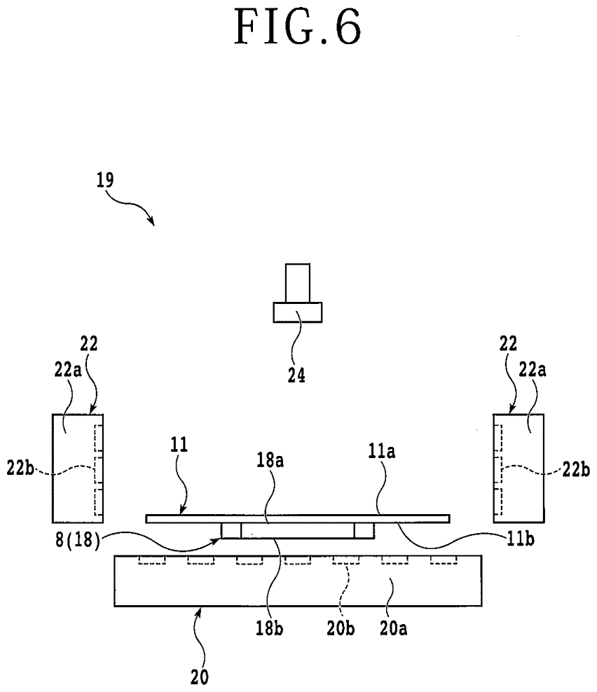

FIG. 6 schematically illustrates, in side elevation, the manner in which the image capturing unit 19 captures an image of a workpiece 11. In preparation for capturing images of the workpiece 11, the surface 18a of the holding unit 18 holds the workpiece 11 such that the face side 11a of the workpiece 11 is exposed and faces upwardly, and the unloading and loading robot 8 is actuated to position the workpiece 11 slightly above the back lighting device 20 and between the oblique lighting devices 22.

For capturing an image of the workpiece 11 that can be used to determine whether foreign matter is attached to the face side 11a or not, the light sources 22b of the oblique lighting device 22 are energized and the camera 24 captures an image of the workpiece 11. In other words, the camera 24 captures an image of the workpiece 11 while the workpiece 11 is being illuminated with light emitted obliquely downwardly from the light sources 22b.

In this case, since the workpiece 11 is illuminated by the oblique lighting devices 22, the intensity of light detected by the light detector of the camera 24 tends to vary largely depending on whether there is foreign matter on the face side 11a of the workpiece 11 or not. Consequently, the image captured by the camera 24 of the workpiece 11 at this time is conducive to making it easy to determine that there is foreign matter on the face side 11a of the workpiece 11 or not.

For capturing an image of the workpiece 11 that can be used to grasp the position of the notch 11c or orientation flat in the workpiece 11, the light sources 20b of the back lighting device 20 as well as the light source of the light emitter 16 of the unloading and loading robot 8 are energized and the camera 24 captures an image of the workpiece 11. In other words, the camera 24 captures an image of the workpiece 11 while the workpiece 11 is being illuminated with light applied from below to the reverse side 11b.

In this case, the workpiece 11 has its entire outer edge illuminated with light from the light emitter 16 and the back lighting device 20. Specifically, the portion of the outer edge of the workpiece 11 that overlaps the holding unit 18 is illuminated with the light from the light emitter 16, whereas the other portion of the outer edge of the workpiece 11 is illuminated with the light from the back lighting device 20. Consequently, the image captured by the camera 24 of the workpiece 11 at this time is conducive to making it easy to grasp the position of the notch 11c or orientation flat in the workpiece 11.

In addition, the last-mentioned image may be used to grasp a deviation, referred to as “on-delivery deviation,” as viewed in plan between a reference point on the unloading and loading robot 8 and the center of the workpiece 11 with the face side 11a facing upwardly. The reference point refers to a point that, when aligned with the center of the workpiece 11 as viewed in plan, makes it possible for the holding unit 18 to hold the workpiece 11 most stably.

Specifically, the positions of at least three points, i.e., their coordinates in a horizontal plane, included in the outer edge of the workpiece 11 can be specified on the basis of the captured image. Then, the position of the center, i.e., its coordinates in a horizontal plan, of the workpiece 11, can be calculated by referring to the specified positions of the at least three points. Therefore, the on-delivery deviation can be grasped on the basis of the image.

### <(4) Foreign Matter Removing Unit>

If it is determined that foreign matter is attached to the face side 11a of the workpiece 11 on the basis of the image captured by the image capturing unit 19, then the unloading and loading robot 8 delivers the workpiece 11 to the foreign matter removing unit 26 (see FIG. 2) before a sheet is fixed to the face side 11a of the workpiece 11. The foreign matter removing unit 26 then removes the foreign matter from the face side 11a.

FIG. 7 schematically illustrates the foreign matter removing unit 26 in perspective. As illustrated in FIG. 7, the foreign matter removing unit 26 includes a cover 28. The cover 28 has a circular opening 28a defined centrally in an upper surface thereof. The circular opening 28a has a diameter larger than the diameter of the workpiece 11. The foreign matter removing unit 26 also includes a disk-shaped spinner table 30 disposed in the circular opening 28a. The spinner table 30 has a disk-shaped frame 30a made of ceramic, for example.

The frame 30a includes a disk-shaped bottom wall and a hollow cylindrical side wall extending upwardly from an outer edge of the bottom wall. The frame 30a has a circular recess defined in its upper surface by the bottom wall and the side wall. A disk-shaped porous plate 30b made of porous ceramic, for example, is fixedly fitted in the circular recess. The upper surface of the frame 30a and the upper surface of the porous plate 30b lie flush with each other and jointly provide a holding surface of the spinner table 30. The outside diameter of the side wall of the frame 30a, i.e., the diameter of the holding surface of the spinner table 30, is smaller than the distance I between the fingers of the holding unit 18 of the unloading and loading robot 8.

The frame 30a has a fluid channel defined therein that is fluidly connected to the porous plate 30b and that is fluidly connectable selectively to a suction source, not depicted, an air supply source, not depicted, and a liquid supply source, not depicted. The suction source includes an ejector, for example. The air supply source includes a tank for storing air, a filter for removing foreign matter contained in the air supplied from the tank, and a regulator for regulating the pressure of the air supplied from the tank, for example. The liquid supply source includes a tank for storing a liquid such as water and a pump for delivering the liquid from the tank, for example.

A target object from which foreign matter is to be removed, specifically a workpiece 11 with or without a sheet fixed thereto, is placed on the upper surface of the porous plate 30b. When the suction source is fluidly connected to the fluid channel in the frame 30a and actuated, it develops a negative pressure in the fluid channel and hence the porous plate 30b, thereby generating a suction force in a space near the upper surface of the porous plate 30b. Therefore, the target object placed on the spinner table 30 is held under suction on the holding surface of the spinner table 30.

Then, while the target object is being placed on the holding surface of the spinner table 30, when the suction source connected to the fluid channel in the frame 30a is turned off and disconnected from the fluid channel and the air supply source is fluidly connected to the fluid channel and actuated, the air supply source supplies air to the fluid channel, bringing the atmospheric pressure back in the fluid channel. The suction force that has acted on the target object is eliminated, freeing the target object from the holding surface of the spinner table 30.

After the target object has been separated from the holding surface of the spinner table 30, when the liquid supply source is fluidly connected to the fluid channel in the frame 30a and actuated, the liquid supply source supplies a liquid through the fluid channel to the holding surface of the spinner table 30, thereby cleaning the holding surface of the spinner table 30.

In addition, the spinner table 30 is coupled to a rotating mechanism 32 for rotating the spinner table 30 about its vertical central axis. The rotating mechanism 32 includes a vertical shaft 32a supporting the spinner table 30 on its upper end, a pulley, not depicted, coaxially mounted on the shaft 32a, and an electric motor, not depicted, for rotating the pulley through an endless belt trained around the pulley and the output shaft of the electric motor.

The spinner table 30 and the rotating mechanism 32 are coupled to a lifting and lowering mechanism, not depicted. The lifting and lowering mechanism includes an air actuator such as an air cylinder, for example, capable of selectively lifting and lowering the spinner table 30 and the rotating mechanism 32. When the lifting and lowering mechanism is actuated, the spinner table 30 can be positioned above or below the upper surface of the cover 28.

A fluid ejecting mechanism 34 is disposed in the vicinity of the spinner table 30. The fluid ejecting mechanism 34 includes a nozzle 34a whose open lower end faces downwardly. The nozzle 34a has an open upper end connected to a distal end of a pipe 34b extending horizontally over the cover 28. The pipe 34b has a proximal end, remote from the nozzle 34a, coupled to an upper end of a vertical pipe 34c.

The vertical pipe 34c extends vertically through the cover 28 and is fluidly connected to a fluid supply source, not depicted, capable of supplying a fluid that may be a gas such as air and/or a liquid such as water, for example. The fluid supply source includes a tank for storing a gas such as air, a filter for removing foreign matter contained in the gas supplied from the tank, and a regulator for regulating the pressure of the gas supplied from the tank, for example. Moreover, the fluid supply source may include, in addition to or instead of the above components, a tank for storing a liquid such as water and a pump for delivering the liquid from the tank, for example.

The pipe 34c has a lower end coupled to an electric motor, not depicted, for rotating the pipe 34c about its longitudinal central axis. When the electric motor is energized, it rotates the pipe 34c about its longitudinal central axis to bring the nozzle 34a to either a position over the opening 28a in the cover 28 as viewed in plan or a position off the opening 28a as viewed in plan.

The foreign matter removing unit 26 may further include a brushing mechanism, not depicted, for brushing a target object held on the holding surface of the spinner table 30. The brushing mechanism has a brush such as a paint brush, for example. By keeping the brush in contact with the target object and moving the brush on the target object, the foreign matter removing unit 26 can remove foreign matter that may have been attached to the target object.

In preparation for removing foreign matter from the target object, i.e., the workpiece 11, with the foreign matter removing unit 26, the electric motor of the fluid ejecting mechanism 34 is energized to position the nozzle 34a of the fluid ejecting mechanism 34 in the position off the opening 28a as viewed in plan. Then, the lifting and lowering mechanism is actuated to position the spinner table 30 above the upper surface of the cover 28.

Then, the workpiece 11 with the face side 11a exposed upwardly is held on the surface 18a of the holding unit 18 of the unloading and loading robot 8, and the unloading and loading robot 8 is actuated to position the workpiece 11 over the spinner table 30. In a case where the on-delivery deviation referred to above has been grasped, the unloading and loading robot 8 should preferably be actuated to position the center of the workpiece 11 directly above the center of the spinner table 30 in view of the on-delivery deviation.

Then, the unloading and loading robot 8 is actuated to lower the workpiece 11 until the reverse side 11b thereof contacts the holding surface of the spinner table 30. Then, the unloading and loading robot 8 is actuated to separate the workpiece 11 from the holding unit 18. Thereafter, the suction source fluidly connected to the fluid channel in the frame 30a of the spinner table 30 is actuated to hold the workpiece 11 under suction on the holding surface of the spinner table 30.

Then, the unloading and loading robot 8 is actuated to position the holding unit 18 in a position off the opening 28a in the cover 28. The lifting and lowering mechanism is actuated to position the spinner table 30 below the upper surface of the cover 28. Thereafter, the electric motor of the fluid ejecting mechanism 34 is energized to position the nozzle 34a thereof over the workpiece 11 on the spinner table 30 as viewed in plan.

Then, the electric motor of the fluid ejecting mechanism 34 is energized, the fluid supply source of the fluid ejecting mechanism 34 is actuated, and the electric motor of the rotating mechanism 32 is energized, respectively to swing the nozzle 34a, to eject the fluid, e.g., a gas, from the nozzle 34a toward the face side 11a of the workpiece 11, and to rotate the spinner table 30.

The fluid is supplied from the nozzle 34a to the face side 11a in its entirety to remove foreign matter that may have been attached to the face side 11a. In a case where the foreign matter removing unit 26 includes the brushing mechanism, the brushing mechanism may be actuated to brush the entire face side 11a to remove foreign matter from the face side 11a with the brush before or after the fluid is ejected from the nozzle 34a to the face side 11a.

After the foreign matter removing unit 26 has removed foreign matter from the face side 11a of the workpiece 11, the electric motor of the fluid ejecting mechanism 34 is energized to position the nozzle 34a in the position off the opening 28a in the cover 28 as viewed in plan. Then, the lifting and lowering mechanism is actuated to position the spinner table 30 above the upper surface of the cover 28.

Thereafter, the suction source connected to the fluid channel in the frame 30a is turned off and disconnected from the fluid channel and the air supply source is fluidly connected to the fluid channel and actuated to keep the workpiece 11 simply placed on the holding surface of the spinner table 30. Then, the other surface 18b of the holding unit 18 is brought into contact with the face side 11a of the workpiece 11 and holds the workpiece 11 under suction thereon, after which the unloading and loading robot 8 is operated to unload the workpiece 11 out of the foreign matter removing unit 26.

### <(5) Preparing Unit>

A sheet to be fixed to the face side 11a of the workpiece 11 is prepared by a preparing unit 36 (see FIG. 2). Specifically, the preparing unit 36 prepares an individual sheet from a stock roll of sheet by reeling out a desired portion from the stock roll of sheet and cutting the desired portion. The individual sheet includes a region to be fixed (hereinafter referred to as “to-be-fixed region”) that is of a shape commensurate with the face side 11a of the workpiece 11 and an excess region surrounding the to-be-fixed region. The shape commensurate with the face side 11a of the workpiece 11 represents, for example, a circular shape whose outer edge coincides with the outer edge of the workpiece 11 except for the notch 11c or orientation flat or a circular shape concentric with the former circular shape, the latter circular shape having a radius that is larger than the radius of the former circular shape by a predetermined offset.

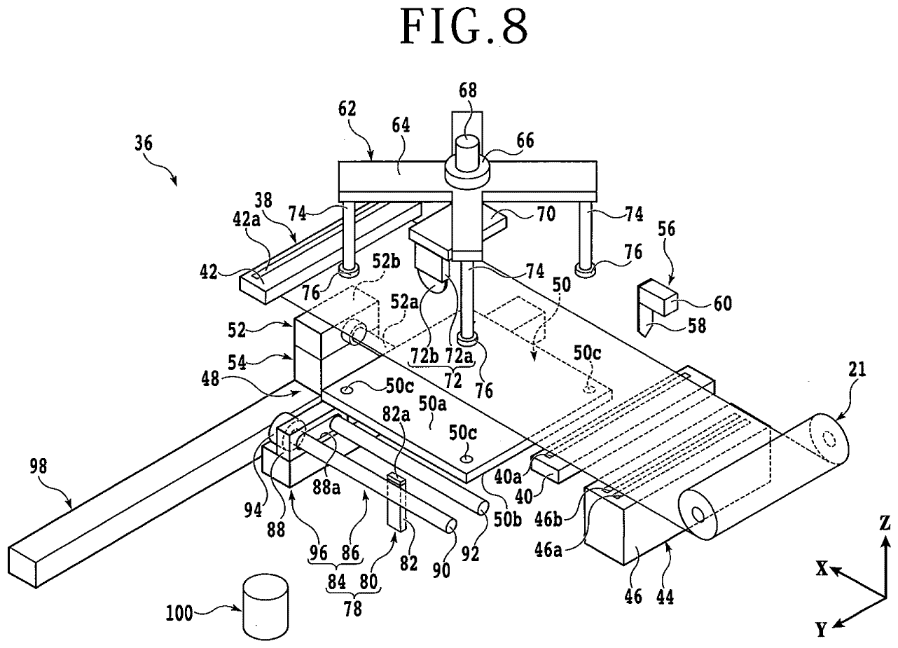

FIG. 8 schematically illustrates the preparing unit 36 in perspective. In FIG. 8, the preparing unit 36 is illustrated in reference to a three-dimensional coordinate system having an X-direction indicated by the arrow X, a Y-direction indicated by the arrow Y, both extending horizontally in a horizontal plane perpendicularly to each other, and a Z-direction indicated by the arrow Z and extending vertically perpendicularly to the X-direction and the Y-direction. The preparing unit 36 includes a stock roll 21 of sheet whose longitudinal central axis extends along the Y-direction. A desired sheet length is reeled out along the X-direction from a lower end of the stock roll 21 of sheet.

### <(a) Stock Roll of Sheet>

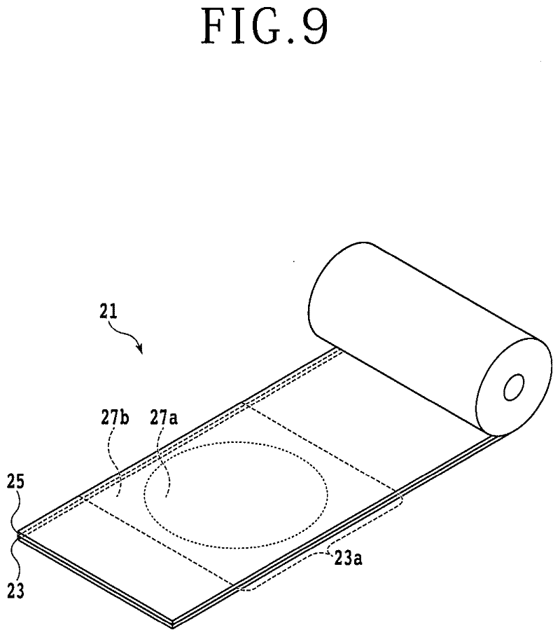

FIG. 9 schematically illustrates the stock roll 21 of sheet in perspective. As illustrated in FIG. 9, the stock roll 21 of sheet includes a rectangular web-shaped sheet 23 whose length is much larger than its width, i.e., a length along the Y-direction, and a protective sheet 25 shaped similarly to the web-shaped sheet 23 and layered with the web-shaped sheet 23 such that the protective sheet 25 is positioned radially inwardly of the web-shaped sheet 23.

The web-shaped sheet 23 has a film-shaped base layer and an adhesive layer disposed on an inner side of the base layer. The base layer includes a synthetic resin such as polypropylene (PP), polyethylene (PE), polyethylene terephthalate (PET), polyvinyl chloride (PVC), or polystyrene (PS), for example. The adhesive layer includes an ultraviolet-curable silicone-based material, acryl-based material, or epoxy-based material.

The protective sheet 25 includes a release film and has a film-shaped base layer and a peel-off layer disposed on a side of the base layer that is closer to the web-shaped sheet 23. The base layer includes a synthetic resin such as PP, PE, or PET, for example. The peel-off layer includes a silicone-based material such as a fluorine-containing silicone-based material or a non-silicone-based material, for example.

The web-shaped sheet 23 includes a portion 23a, to be cut off into an individual sheet, reeled out from the stock roll 21 of sheet. The portion 23a includes a to-be-fixed region 27a positioned centrally therein and commensurate in shape with the face side 11a of the workpiece 11 and an excess region 27b surrounding the to-be-fixed region 27a.

Providing the face side 11a of the workpiece 11 is of a circular shape having a diameter of 300 mm, for example, the portion 23a is of a square shape having four sides each having a length in the range of 320 to 380 mm, typically a length of 350 mm. In this case, the to-be-fixed region 27a is of a circular shape having a diameter of 300 mm and the excess region 27b is of a shape including a circular inner peripheral edge having a diameter of 300 mm and a square outer peripheral edge having four sides each having a length in the range of 320 to 380 mm.

### <(b) Withdrawal Assembly and Foreign Matter Removing Device>

The preparing unit 36 includes a withdrawal assembly 38 (see FIG. 8) for withdrawing the portion 23a from the stock roll 21 of sheet. The withdrawal assembly 38 includes a fixed member 40 and a movable member 42 each having a width, i.e., a length along the Y-direction, that is larger than the width of the stock roll 21 of sheet.

The fixed member 40 has an upper surface parallel to the X-direction and the Y-direction for supporting thereon the layered structure of the web-shaped sheet 23 and the protective sheet 25 that is reeled out from the stock roll 21 of sheet. The fixed member 40 has a groove 40a defined in the upper surface thereof. The groove 40a extends along the Y-axis and has a length larger than the width of the stock roll 21 of sheet.

The movable member 42 is positioned upwardly from the fixed member 40 by a distance that is essentially equal to the thickness of the layered structure of the web-shaped sheet 23 and the protective sheet 25. The movable member 42 has a lower surface parallel to the X-direction and the Y-direction. The movable member 42 has a through passage 42a defined therethrough along the Z-direction. The through passage 42a extends along the Y-direction and has a length essentially equal to the length of the groove 40a.

The movable member 42 is coupled to an X-direction moving mechanism, not depicted. The X-direction moving mechanism includes a support plate secured to an end of the movable member 42, a ball screw for moving the support plate along the X-direction, and an electric motor for rotating a screw shaft of the ball screw about its longitudinal central axis. When the electric motor is energized, it rotates the screw shaft, causing the support plate and hence the movable member 42 to move along the X-direction between a position near the stock roll 21 of sheet, i.e., a near position, and a position far from the stock roll 21 of sheet, i.e., a far position.

Specifically, the near position refers to a position where the groove 40a defined in the upper surface of the fixed member 40 and the through passage 42a defined through the movable member 42 overlap each other along the Z-direction. The far position refers to a position that is spaced along the X-direction from the close position by a predetermined distance that is larger than the length of the portion 23a.

In FIG. 8, the movable member 42 is illustrated as being positioned in the far position. When the movable member 42 is positioned in the near position, the layered structure of the web-shaped sheet 23 and the protective sheet 25 that is supported on the fixed member 40 is gripped between the fixed member 40 and the movable member 42.

The movable member 42 has a plurality of suction holes, not depicted, defined in a lower surface thereof at a side that is closer to the stock roll 21 of sheet than the through passage 42a. The suction holes are fluidly connected selectively to a suction source, not depicted, and an air supply source, not depicted. The suction source includes an ejector, for example. The air supply source includes a tank for storing air, a filter for removing foreign matter contained in the air supplied from the tank, and a regulator for regulating the pressure of the air supplied from the tank, for example.

When the suction source is connected to the suction holes and actuated, it develops a negative pressure in the suction holes, thereby generating a suction force in a space near the lower surface of the movable member 42 at the side that is closer to the stock roll 21 of sheet than the through passage 42a. When the suction source connected to the suction holes is turned off and disconnected from the suction holes and the air supply source is connected to the suction holes and actuated, the air supply source supplies air to the suction holes, bringing the atmospheric pressure back in the suction holes thereby to eliminate the suction force.

A foreign matter removing device 44 for removing foreign matter attached to the portion 23a is disposed between the fixed member 40 of the withdrawal assembly 38 and the stock roll 21 of sheet as viewed in plan. The foreign matter removing device 44 has a cuboid case 46 positioned below the layered structure of the web-shaped sheet 23 and the protective sheet 25, an electrostatic eliminator, not depicted, and a suction device, not depicted, that are housed in the cuboid case 46.

The electrostatic eliminator applies air and ions upwardly through a first through passage 46a defined in an upper panel of the case 46 in order to remove electrostatic charges from the lower surface of the layered structure of the web-shaped sheet 23 and the protective sheet 25, specifically, from the lower surface of the web-shaped sheet 23. The first through passage 46a extends along the Y-direction and has a length larger than the width of the stock roll 21 of sheet.

The suction device applies a suction force upwardly through a second through passage 46b defined in the upper panel of the case 46 at a position remoter from the stock roll 21 of sheet than the first through passage 46a to a space above the case 46 in order to remove foreign matter attached to the lower surface of the layered structure of the web-shaped sheet 23 and the protective sheet 25. The second through passage 46b extends along the Y-direction and has a length essentially equal to the length of the first through passage 46a.

The preparing unit 36 may additionally have another foreign matter removing device that is structurally identical to the foreign matter removing device 44 in vertical face-to-face alignment with the foreign matter removing device 44 with the layered structure of the web-shaped sheet 23 and the protective sheet 25 interposed therebetween. The additional foreign matter removing device removes electrostatic charges from the upper surface of the layered structure of the web-shaped sheet 23 and the protective sheet 25, specifically, from the upper surface of the protective sheet 25, and removes foreign matter attached to the upper surface of the layered structure of the web-shaped sheet 23 and the protective sheet 25.

For withdrawing the portion 23a from the stock roll 21 of sheet, the X-direction moving mechanism is actuated to enable the fixed member 40 and the movable member 42 to grip the layered structure of the web-shaped sheet 23 and the protective sheet 25 supported on the fixed member 40, i.e., to position the movable member 42 in the near position.

Then, the suction source is connected to the suction holes defined in the lower surface of the movable member 42 and actuated to apply a suction force to the layered structure of the web-shaped sheet 23 and the protective sheet 25. The layered structure of the web-shaped sheet 23 and the protective sheet 25 is thus attracted under suction to the lower surface of the movable member 42.

Then, while the foreign matter removing device 44 or the other foreign matter removing device or both, i.e., its electrostatic eliminator and suction device or their electrostatic eliminators and suction devices, are being actuated, the X-direction moving mechanism is actuated to move the portion 23a across the foreign matter removing device 44 until the movable member 42 reaches the far position. In this manner, the portion 23a with the amount of foreign matter being reduced is reeled off from the stock roll 21 of sheet between the near position and the far position.

### <(c) Holding Unit>

A holding unit 48 for holding the portion 23a is disposed beneath the portion 23a withdrawn by the withdrawal assembly 38. The holding unit 48 has a holding plate 50 for holding the portion 23a thereon. The holding plate 50 is of a square shape having four sides each having a length essentially equal to the width of the stock roll 21 of sheet. The holding plate 50 has a surface 50a and an opposite surface 50b that lie parallel to each other.

The holding plate 50 also has suction holes 50c defined in the surface 50a respectively the four corners thereof. The four suction holes 50c are fluidly connected selectively to a suction source, not depicted, and an air supply source, not depicted. The suction source includes an ejector, for example. The air supply source includes a tank for storing air, a filter for removing foreign matter contained in the air supplied from the tank, and a regulator for regulating the pressure of the air supplied from the tank, for example.

When the suction source is connected to the suction holes 50c and actuated, it develops a negative pressure in the suction holes 50c, thereby generating a suction force in spaces near the surface 50a at the four corners of the holding plate 50. When the suction source connected to the suction holes 50c is turned off and disconnected from the suction holes 50c and the air supply source is connected to the suction holes 50c and actuated, the air supply source supplies air to the suction holes 50c, bringing the atmospheric pressure back in the suction holes 50c thereby to eliminate the suction force.

The holding plate 50 is coupled to a rotating mechanism 52. The rotating mechanism 52 includes a cylindrical shaft 52a extending along the X-direction and secured to the center in the Y-direction of the opposite surface 50b of the holding plate 50 and an electric motor 52b for rotating the shaft 52a about its longitudinal central axis. When the electric motor 52b is energized, it rotates the shaft 52a about its longitudinal central axis to turn the holding plate 50 upside down.

The rotating mechanism 52 is also coupled to a Z-direction moving mechanism 54. The Z-direction moving mechanism 54 includes an actuator such as an air cylinder capable of selectively lifting and lowering a rod whose upper end is secured to the electric motor 52b. When the Z-direction moving mechanism 54 is actuated, it lifts or lowers the rotating mechanism 52 and hence the holding plate 50.

When the portion 23a is reeled out from the stock roll 21 of sheet by the withdrawal assembly 38, the portion 23a is held by the holding unit 48. Specifically, the rotating mechanism 52 is actuated to turn the holding plate 50 until the surface 50a thereof faces upwardly. Then, the Z-direction moving mechanism 54 is actuated to lift the holding plate 50 until the surface 50a thereof is brought into contact with the portion 23a.

Thereafter, the suction source fluidly connected to the suction holes 50c in the four corners of the surface 50a of the holding plate 50 are actuated to apply a suction force to the portion 23a. The portion 23a is now held under suction on the surface 50a of the holding plate 50.

### <(d) Cutting Unit>

A cutting unit 56 for cutting off the portion 23a from the stock roll 21 of sheet is disposed directly above the fixed member 40. The cutting unit 56 has a cutter 58 positioned directly above the groove 40a defined in the upper surface of the fixed member 40 and having a cutting edge directed downwardly. The cutting unit 56 also includes a support member 60 having a distal end secured to an upper side of the cutter 58.

The support member 60 is coupled to a Y-direction and Z-direction moving mechanism, not depicted. The Y-direction and Z-direction moving mechanism includes a Y-direction support plate secured to a proximal end of the support member 60, a Y-direction ball screw for moving the Y-direction support plate along the Y-direction, and a Y-direction electric motor for rotating a screw shaft of the Y-direction ball screw about its longitudinal central axis, for example. When the Y-direction electric motor is energized, it rotates the screw shaft of the Y-direction ball screw about its longitudinal central axis, causing the Y-direction support plate and hence the support member 60 and the cutter 58 to move along the Y-direction.

The Y-direction and Z-direction moving mechanism also includes a Z-direction support plate secured to the Y-direction ball screw and the Y-direction electric motor, a Z-direction ball screw for moving the Z-direction support plate along the Z-direction, and a Z-direction electric motor for rotating a screw shaft of the Z-direction ball screw about its longitudinal central axis, for example. When the Z-direction electric motor is energized, it rotates the screw shaft of the Z-direction ball screw about its longitudinal central axis, causing the Z-direction support plate and hence the Y-direction support plate, the Y-direction ball screw, the Y-direction electric motor, the support member 60, and the cutter 58 to move along the Z-direction.

When the portion 23a is held by the holding unit 48, as described above, the suction source connected to the suction holes defined in the lower surface of the movable member 42 is turned off and disconnected and the air supply source is connected to the suction holes and actuated, bringing the atmospheric pressure back in the suction holes. Now, the portion 23a is not attracted under suction to the lower surface of the movable member 42 and separated from the movable member 42 by gravity.

Then, the X-direction moving mechanism is actuated to bring the through passage 42a defined through the movable member 42 and the groove 40a defined in the fixed member 40 into alignment with each other along the Z-direction, i.e., to position the movable member 42 in the near position. Thereafter, the Y-direction and Z-direction moving mechanism is actuated to position a pointed cutting edge of the cutter 58 at an end of the groove 40a in the Y-direction.

Then, the Y-direction and Z-direction moving mechanism is actuated to move the pointed cutting edge of the cutter 58 across the layered structure of the web-shaped sheet 23 and the protective sheet 25 from one side to the other along the Y-direction. The cutter 58 now severs the layered structure of the web-shaped sheet 23 and the protective sheet 25 along the Y-direction, cutting off the portion 23a as an individual sheet from the stock roll 21 of sheet.

### <(e) Blanking Unit>

A blanking unit 62 for blanking out a region, i.e., a to-be-peeled-off region, from the protective sheet 25 that is to overlie the to-be-fixed region 27a of the individual sheet is disposed in the vicinity of the cutting unit 56, but spaced therefrom along the X-direction. The blanking unit 62 has a support member 64 that is of a criss-cross shape as viewed in plan and that has a through hole defined centrally therethrough. A vertical shaft 68 is rotatably supported in the through hole by a bearing 66.

The shaft 68 has an upper end coupled to an electric motor, not depicted, for rotating the shaft 68 about its longitudinal central axis and a lower end coupled to the upper surface of an end of a plate-shaped joint 70 extending horizontally, i.e., perpendicularly to the Z-direction. A cutting tool 72 is mounted on the lower surface of an opposite end of the joint 70.

The cutting tool 72 includes a cover 72a shaped as a rectangular tube and a round cutter 72b partly housed in the cover 72a and having a round cutting edge exposed downwardly out of the cover 72a. The cover 72a also houses an electric motor, not depicted for rotating the round cutter 72b about its central axis that extends horizontally, i.e., perpendicularly to the Z-direction.

The longitudinal central axis about which the shaft 68 is rotatable and the lower end of the round cutter 72b are spaced from each other by a horizontal distance that is slightly larger than the radius of the face side 11a of the workpiece 11 as viewed in plan. For example, if the radius of the face side 11a of the workpiece 11 is 150 mm, then the horizontal distance is of a value in the range of 150.0 to 155 mm, typically a value of 152.5 mm.

Four cylindrical rods 74 that extend vertically along the Z-axis direction have respective upper ends secured respectively to the lower surfaces of four outer ends of the support member 64. The rods 74 have respective lower ends on which there are mounted respective elastic pads 76 made of synthetic resin that have circular horizontal lower surfaces essentially parallel to the X-direction and the Y-directions.

When the individual sheet is cut off from the stock roll 21 of sheet by the cutting unit 56, as described above, each of the elastic pads 76 is positioned directly above either one of the four suction holes 50c defined in the surface 50a of the holding plate 50. The lower surfaces of the elastic pads 76 are positioned generally at the same height as the lower end of the round cutter 72b.

In addition, the support member 64 is coupled to a Z-direction moving mechanism, not depicted. The Z-direction moving mechanism includes a support plate secured to the support member 64, a ball screw for moving the support plate along the Z-direction, and an electric motor for rotating a screw shaft of the ball screw about its longitudinal central axis, for example. When the electric motor is energized, it rotates the screw shaft, causing the support plate and hence the cutting tool 72 and the elastic pads 76 to move along the Z-direction.

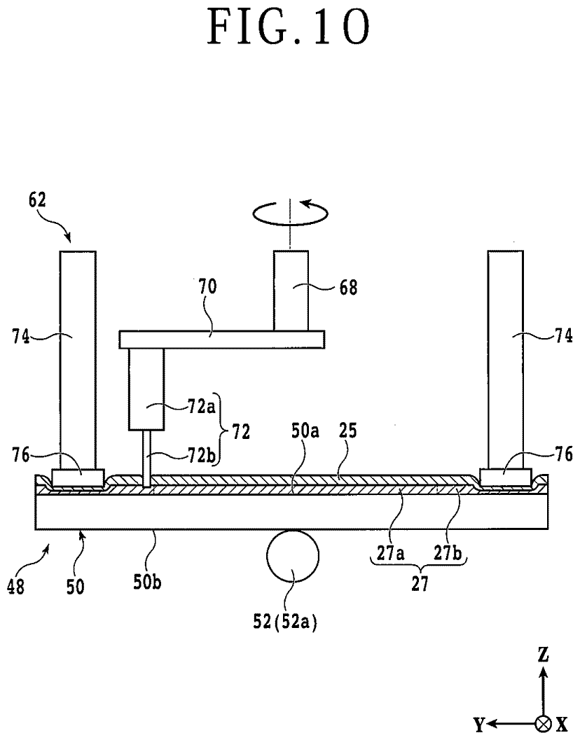

After the individual sheet has been cut off from the stock roll 21 of sheet by the cutting unit 56, as described above, the blanking unit 62 blanking out a to-be-peeled-off region from the protective sheet 25. FIG. 10 schematically illustrates, in side elevation, the manner in which some components of a preparing unit 36 operate to blank out a to-be-peeled-off region of the protective sheet 25. FIG. 10 illustrates the individual sheet 27 and the protective sheet 25 in cross section.

For blanking out a to-be-peeled-off region of the protective sheet 25, the Z-direction moving mechanism coupled to the support member 64 is actuated to lower the round cutter 72b until the lower end of the round cutter 72b goes through the protective sheet 25 to a position within the individual sheet 27. Then, the electric motor coupled to the upper end of the shaft 68 is energized to rotate the round cutter 72b to make at least one revolution, thereby blanking out a to-be-peeled-off region of the protective sheet 25.

While the blanking unit 62 is blanking out a to-be-peeled-off region of the protective sheet 25, a layered structure of the individual sheet 27 and the protective sheet 25 is elastically deformed by being pressed against the surface 50a of the holding plate 50 by the elastic pads 76 in the vicinity of the four corners of the surface 50a of the holding plate 50. Therefore, the individual sheet 27 and the protective sheet 25 are prevented from being positionally displaced in their layered structure during the blanking step.

The blanking step may be carried out while the round cutter 72b itself is being or not being rotated about its central axis by the electric motor housed in the cover 72a. However, if the blanking step is carried out while the round cutter 72b itself is not being rotated about its central axis, then the round cutting edge of the round cutter 72b is unduly worn only near its lower end and hence is likely to lose its cutting ability too soon.

For the reason described above, providing the blanking step is carried out n times (n is a natural number of 2 or more) while the round cutter 72b itself is not being rotated about its central axis, the part of the round cutting edge of the round cutter 72b that is to be used in the blanking step should preferably be replaced with another part of the round cutting edge each time the blanking step is carried out once or m times (m is a natural number 2 or more and lower than n). Specifically, after the blanking step has been carried out in a first cycle and before the blanking step is carried out in a second cycle, or more generally the blanking step has been carried out m times and before the blanking step is carried out (m+1) times, the electric motor housed in the cover 72a may be energized to turn the round cutter 72b through a predetermined angle, e.g., 12°, about its central axis.

### <(f) Peeling Unit>

A peeling unit 78 (see FIG. 8) for peeling off the to-be-peeled-off region of the protective sheet 25 from the individual sheet 27 is disposed directly below the blanking unit 62. The peeling unit 78 includes an initially processing section 80 for peeling off a peel-off initiating portion of the to-be-peeled-off region of the protective sheet 25 from the individual sheet 27 and a subsequently processing section 84 for peeling off a remainder of the to-be-peeled-off region of the protective sheet 25 from the individual sheet 27.

The initially processing section 80 includes an actuator, not depicted, such as an air cylinder, including a cuboid rod 82 extending along the Z-direction, for selectively lifting and lowering the cuboid rod 82. The cuboid rod 82 is positioned immediately below a location on the to-be-peeled-off region blanked out of the protective sheet 25 by the blanking unit 62, spaced slightly radially inwardly from an end of the to-be-peeled-off region in the Y-direction.

The cuboid rod 82 includes an upper adhering end 82a that can adhere to an object that the cuboid rod 82 has contacted. The adhering end 82a may be made of an adhesive gel or may alternatively be of a structure, e.g., a suction pad, for developing a lower pressure in a space near the surface of the object that the cuboid rod 82 has contacted than the pressure outside of the space.

The initially processing section 80 may be of any structure as long as it can peel off the peel-off initiating portion of the to-be-peeled-off region of the protective sheet 25 from the individual sheet 27. For example, the initially processing section 80 may include, instead of the actuator, a claw- or needle-shaped member and an introducing mechanism for introducing the claw- or needle-shaped member into the interface between the to-be-peeled-off region of the protective sheet 25 and the individual sheet 27. Alternatively, the initially processing section 80 may include, rather than the actuator, an injecting mechanism for injecting air into the interface between the to-be-peeled-off region of the protective sheet 25 and the individual sheet 27.

The initially processing section 80 may further include a clamp mechanism, not depicted, for gripping a layered structure of the individual sheet 27 and a region of the protective sheet 25 other than the to-be-peeled-off region thereof so as to peel off the peel-off initiating portion smoothly. Specifically, the clamp mechanism grips a portion of the layered structure near the peel-off initiating portion, for example, at the time the peel-off initiating portion of the to-be-peeled-off region of the protective sheet 25 is peeled off from the individual sheet 27.

The subsequently processing section 84 includes a pay-out mechanism 86. The pay-out mechanism 86 includes a case 88 shaped as a rectangular parallelepiped extending along the Y-direction and having an opening 88a defined in a side plate thereof and extending along the Y-direction. The case 88 supports thereon a drive roller 90 and a driven roller 92 that are rotatable about respective longitudinal central axes thereof along the X-direction.

Each of the drive roller 90 and the driven roller 92 extends along the X-direction and has a proximal end inserted in the opening 88a in the side plate of the case 88. The drive roller 90 extends through the case 88 along the X-direction with an electric motor 94 coupled to the proximal end thereof.

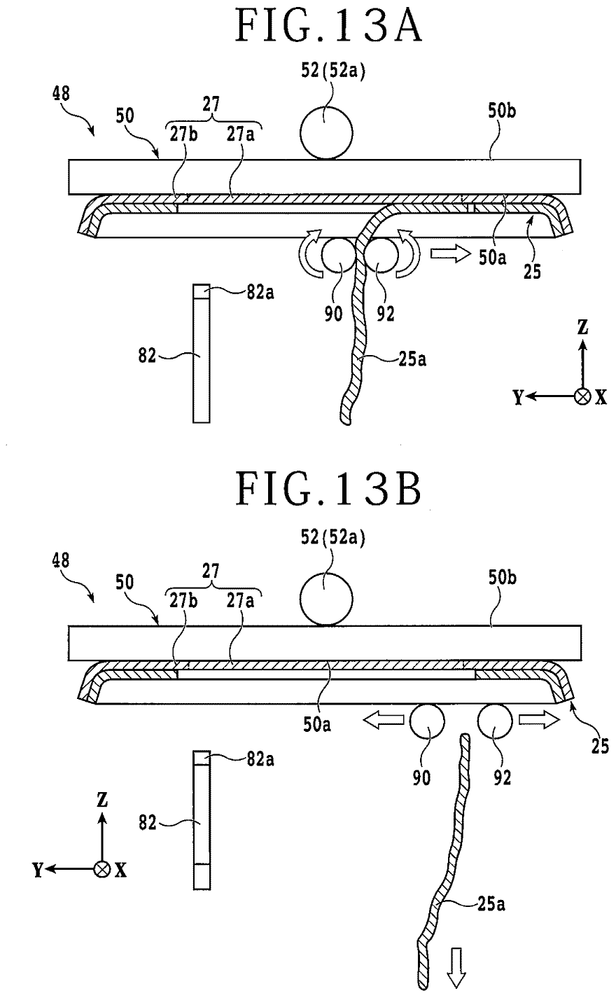

The electric motor 94 is securely mounted on a side plate of the case 88 opposite the side plate having the opening 88a defined therein. When the electric motor 94 is energized, it rotates the drive roller 90 about its longitudinal central axis, e.g., clockwise as viewed in side elevation (see FIG. 13A).

The case 88 houses therein an actuator, not depicted, for adjusting the distance between the drive roller 90 and the driven roller 92 in the Y-direction. The actuator is able to move the drive roller 90 and the driven roller 92 relatively to each other in a manner to space them away from each other by a distance larger than the width of the rod 82 along the Y-direction and to bring them toward each other until they contact each other.

When the electric motor 94 is energized while the drive roller 90 and the driven roller 92 are being held in contact with each other, the torque of the drive roller 90 is transmitted to the driven roller 92, causing the driven roller 92 to rotate about its longitudinal central axis in a direction opposite the driven roller 92, e.g., counterclockwise as viewed in side elevation (see FIG. 13A).

In addition, the case 88 is coupled to a Y-direction moving mechanism 96. In FIG. 8, the Y-direction moving mechanism 96 is illustrated as a block shaped as a rectangular parallelepiped extending along the Y-direction for illustrative purposes. The Y-direction moving mechanism 96 includes, for example, a support plate secured to a lower side of the case 88, a ball screw for moving the support plate along the Y-direction, and an electric motor for rotating a screw shaft of the ball screw about its longitudinal central axis.

When the Y-direction moving mechanism 96 is actuated, it moves the case 88 and hence the drive roller 90 and the driven roller 92 along the Y-direction between an initial position and a terminal position. Specifically, the initial position refers to a position below the end of the to-be-peeled-off region in the Y-direction at the time the to-be-peeled-off region is blanked out of the protective sheet 25 by the blanking unit 62, as described above.

When the actuator housed in the case 88 is operated to space the drive roller 90 and the driven roller 92 from each other in the initial position, the rod 82 is positioned between the drive roller 90 and the driven roller 92 as viewed in plan. The terminal position refers to a position below a diametrically opposite end of the to-be-peeled-off region in the Y-direction.

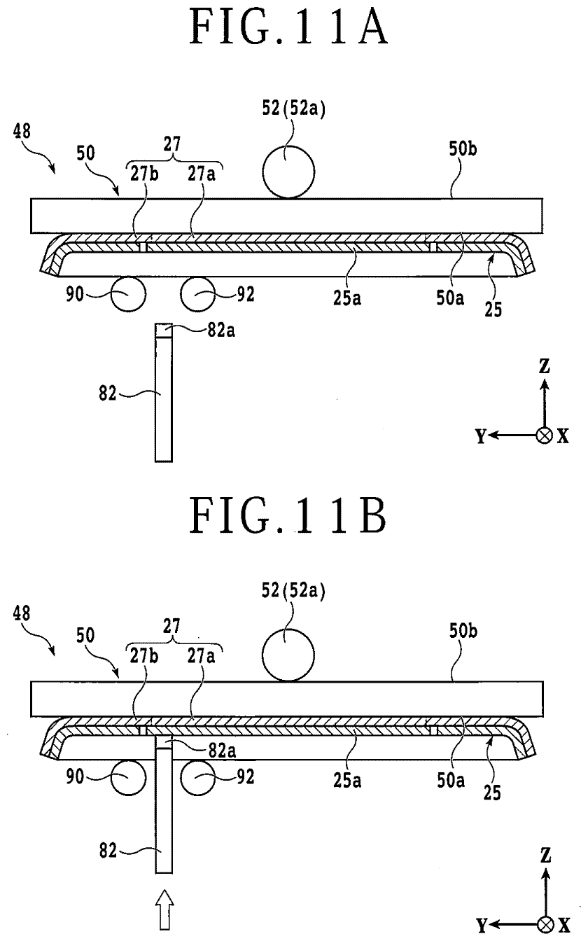

After the to-be-peeled-off region has been blanked out of the protective sheet 25 by the blanking unit 62, the to-be-peeled-off region is peeled off from the individual sheet 27. Each of FIGS. 11A, 11B, 12A, 12B, 13A, and 13B schematically illustrates, in side elevation, some components of the preparing unit 36 operate to peel off the to-be-peeled-off region of the protective sheet 25 from the individual sheet 27. In FIGS. 11A, 11B, 12A, 12B, 13A, and 13B, the individual sheet 27 and the protective sheet 25 are illustrated in cross section.

For peeling off the to-be-peeled-off region from the individual sheet 27, the Y-direction moving mechanism 9 is actuated to place the drive roller 90 and the driven roller 92 in the initial position and the actuator housed in the case 88 is operated to space the drive roller 90 and the driven roller 92 from each other by a distance larger than the width of the rod 82 along the Y-direction.

Then, the rotating mechanism 52 is actuated to turn the layered structure of the individual sheet 27 and the protective sheet 25 held on the surface 50a of the holding plate 50 to face downwardly (see FIG. 11A). The upper adhering end 82a of the rod 82 now faces the location on the to-be-peeled-off region, denoted by 25a, of the protective sheet 25, spaced slightly radially inwardly from the end of the to-be-peeled-off region in the Y-direction, in the Z-direction.

At this time, the layered structure of the individual sheet 27 and the protective sheet 25 does not drop off the holding plate 50 because it is attracted under suction to the holding plate 50 because of the suction force acting through the suction holes 50c defined in the four corners of the surface 50a of the holding plate 50. However, the portion of the layered structure of the individual sheet 27 and the protective sheet 25 that is positioned outwardly of the suction holes 50c is sagging due to gravity.

Then, the initially processing section 80 is actuated to lift the rod 82 until the adhering end 82a thereof as it moves upwardly through the space between the drive roller 90 and the driven roller 92 is pressed against the portion of the to-be-peeled-off region 25a of the protective sheet 25 that is spaced slightly inwardly of the end thereof in the Y-direction (see FIG. 11B). The adhering end 82a of the rod 82 now adheres to the portion of the to-be-peeled-off region 25a. Providing the initially processing section 80 includes a clamp mechanism referred to above, the initially processing section 80 may be actuated to cause the clamp mechanism to grip the sagging portion of the layered structure of the individual sheet 27 and the protective sheet 25 before the rod 82 is lifted.

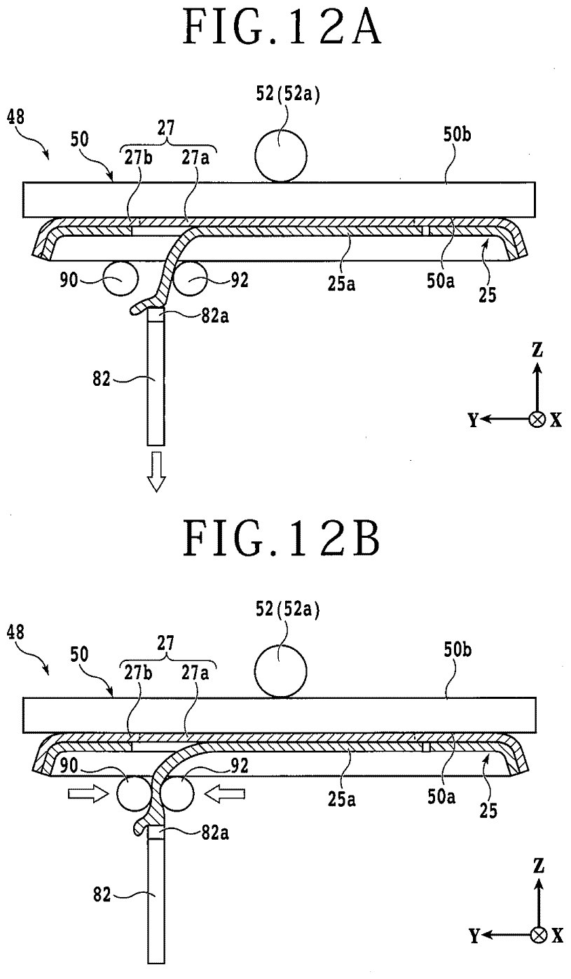

Then, the initially processing section 80 is actuated to lower the rod 82 until the adhering end 82a thereof as it moves downwardly through the space between the drive roller 90 and the driven roller 92 is positioned below the drive roller 90 and the driven roller 92 (see FIG. 12A). The peel-off initiating portion of the to-be-peeled-off region 25a of the protective sheet 25 is peeled off from the individual sheet 27 and positioned between the drive roller 90 and the driven roller 92 by the adhering end 82a.

Then, the actuator housed in the case 88 is operated to move the drive roller 90 and the driven roller 92 toward each other (see FIG. 12B). The peel-off initiating portion of the to-be-peeled-off region 25a of the protective sheet 25 is now pinched between the drive roller 90 and the driven roller 92.

Then, while the electric motor 94 is being energized to rotate both the drive roller 90 and the driven roller 92, the driven roller 92 being rotated by the torque transmitted thereto from the drive roller 90 through the to-be-peeled-off region 25a, the Y-direction moving mechanism 96 is actuated to move the drive roller 90 and the driven roller 92 from the initial position to the terminal position (see FIG. 13A). The movement of the drive roller 90 and the driven roller 92 applies a force to the to-be-peeled-off region 25a to promote the peeling-off thereof from the individual sheet 27 while at the same time the drive roller 90 and the driven roller 92 are jointly paying out the to-be-peeled-off region 25a downwardly. The to-be-peeled-off region 25a is thus further peeled off from the individual sheet 27.

As the to-be-peeled-off region 25a is thus peeled off from the individual sheet 27, the adhering end 82a of the rod 82 should preferably be separate from the portion of the to-be-peeled-off region 25a to which the adhering end 82a adhered. Therefore, when the to-be-peeled-off region 25a is peeled off the individual sheet 27, it is preferable to move the drive roller 90 and the driven roller 92 at an increased speed toward the terminal position so as to pull the to-be-peeled-off region 25a away from the adhering end 82a of the rod 82.

Specifically, when the to-be-peeled-off region 25a is peeled off the individual sheet 27, the speed at which the drive roller 90 and the driven roller 92 move toward the terminal position should be higher than the speed (hereinafter referred to as “peel-off speed”) at which the to-be-peeled-off region 25a is peeled off from the individual sheet 27. The peel-off speed is obtained by dividing the length of the to-be-peeled-off region 25a along the Y-direction that has been peeled off in a predetermined time by the predetermined time. The speed at which the drive roller 90 and the driven roller 92 move toward the terminal position should preferably be 1.5 times the peel-off speed and more preferably be 2 times the peel-off speed.

When the drive roller 90 and the driven roller 92 reach the terminal position, the to-be-peeled-off region 25a of the protective sheet 25 is peeled off in its entirety from the individual sheet 27. Then, the actuator housed in the case 88 is operated to space the drive roller 90 and the driven roller 92 from each other (see FIG. 13B). The to-be-peeled-off region 25a that has been peeled off from the individual sheet is discarded into a rubbish bin, not depicted, disposed directly below the terminal position.

### <(g) Feeding Unit and Image Capturing Unit>

The holding unit 48 is coupled to a feeding unit 98 (see FIG. 8). In FIG. 8, the feeding unit 98 is illustrated as a block shaped as a rectangular parallelepiped extending along the Y-direction for illustrative purposes. The feeding unit 98 includes a support plate, not depicted, secured to a lower side of the Z-direction moving mechanism 54, a ball screw for moving the support plate along the Y-direction, and an electric motor for rotating a screw shaft of the ball screw about its longitudinal central axis.

When the feeding unit 98 is actuated, it moves the holding plate 50 along the Y-direction between a processing position and a transferring position. Specifically, the processing position refers to a position where the to-be-peeled-off region 25a of the protective sheet 25 is processed, i.e., peeled off from the individual sheet 27 by the peeling unit 78. The transferring position refers to a position where the individual sheet 27 held on the surface 50a of the holding plate 50 is transferred from the preparing unit 36 to a fixing unit 102 to be described later.

An image capturing unit 100 is disposed on a path to be followed by the holding plate 50 from the processing position toward the transferring position. In FIG. 8, the image capturing unit 100 is illustrated as a cylindrical block for illustrative purposes. The image capturing unit 100 includes a camera including an objective lens, not depicted, and a photodetector such as a CCD image sensor or a CMOS image sensor. The image capturing unit 100 is able to capture images above itself.

The image capturing unit 100 further includes, in addition to the camera, an oblique lighting device disposed in the periphery of the camera. The oblique lighting device emits light such as visible light obliquely upwardly toward an area directly above the camera of the path to be followed by the holding plate 50 from the processing position toward the transferring position.

After the to-be-peeled-off region 25a of the protective sheet 25 has been peeled off from the individual sheet 27 by the peeling unit 78, it is determined whether foreign matter is attached to the to-be-fixed region 27a of the individual sheet 27 or not. Specifically, the feeding unit 98 is actuated to position the holding plate 50 that is supporting on its surface 50a the individual sheet 27 that faces downwardly with the to-be-fixed region 27a being exposed, immediately above the image capturing unit 100.

Then, while the oblique lighting device of the image capturing unit 100 is being energized to emit light obliquely upwardly toward the to-be-fixed region 27a of the individual sheet 27, the camera of the image capturing unit 100 captures an image of the to-be-fixed region 27a. The intensity of light that is detected by the photodetector of the camera tends to vary greatly depending on whether foreign matter is present on the to-be-fixed region 27a or not. Therefore, the image captured of the to-be-fixed region 27a by the camera is effective in determining whether foreign matter is present on the to-be-fixed region 27a or not.

If it is determined from the image that no foreign matter is attached to the to-be-fixed region 27a, then the feeding unit 98 is actuated to position the holding plate 50 with the individual sheet 27 held on its surface 50a in the transferring position. Conversely, if it is determined from the image that foreign matter is attached to the to-be-fixed region 27a, then the individual sheet 27 is discarded.

For discarding the individual sheet 27, specifically, the feeding unit 98 is actuated to position the holding plate 50 that is holding the individual sheet 27 and the protective sheet 25 on its surface 50a in a discarding position between the processing position and the transferring position. Then, the suction source fluidly connected to the suction holes 50c defined in the four corners of the surface 50a of the holding plate 50 is turned off and disconnected from the suction holes 50c and the air supply source is fluidly connected to the suction holes 50c and actuated.

The atmospheric pressure is brought back in the suction holes 50c, releasing the layered structure of the individual sheet 27 and the protective sheet 25 from the surface 50a of the holding plate 50. The layered structure of the individual sheet 27 and the protective sheet 25 now drops off the holding plate 50 due to gravity. As a result, the individual sheet 27 falls into a rubbish bin, not depicted, that is placed immediately below the discarding position, for example.

### <(6) Fixing Unit>

A workpiece 11 and an individual sheet 27 that are adequate for being fixed together are prepared and then introduced into a fixing unit 102 (see FIG. 2). Specifically, the workpiece 11 is introduced into the fixing unit 102 after it has been determined to be free of foreign matter on its face side 11a on the basis of the image captured by the image capturing unit 19. The individual sheet 27 is introduced into the fixing unit 102 after it has been determined to be free of foreign matter on its to-be-fixed region 27a on the basis of the image captured by the image capturing unit 100.

If it is determined that foreign matter is attached to the face side 11a of the workpiece 11, then the foreign matter is removed from the face side 11a of the workpiece 11 by the foreign matter removing unit 26 and thereafter an image of the face side 11a of the workpiece 11 is captured by the image capturing unit 19. If the decision is changed on the basis of the captured image, i.e., if it is determined that no foreign matter is attached to the face side 11a of the workpiece 11, then the workpiece 11 is introduced into the fixing unit 102.

Conversely, if the decision is not changed on the basis of the captured image, i.e., if it is determined again that foreign matter is attached to the face side 11a of the workpiece 11, then the removal of the foreign matter from the face side 11a of the workpiece 11 and the determination based on the image captured of the face side 11a of the workpiece 11 by the image capturing unit 19 are alternately repeated a predetermined number of times.

In a case where the removal of the foreign matter from the face side 11a by the foreign matter removing unit 26 is repeated in a plurality of cycles, operating conditions for the foreign matter removing unit 26 may be changed in each cycle. Specifically, operating conditions in a succeeding cycle, e.g., the flow rate and/or the pressure of the fluid ejected from the nozzle 34a of the fluid ejecting mechanism 34, may be set to a value or values for better removal of the foreign matter from the face side 11a, e.g., to a higher level or levels, than operating conditions in a preceding cycle. If the decision is changed during one of the repeated cycles, then the workpiece 11 is introduced into the fixing unit 102.

In a case where an image of the face side 11a of the workpiece 11 is to be captured by the image capturing unit 19 after foreign matter has been removed from the face side 11a by the foreign matter removing unit 26, the workpiece 11 that has been separated from the holding unit 18 of the unloading and loading robot 8 is held again by the holding unit 18. At this time, a relative positional relation between the notch 11c or orientation flat in the workpiece 11 and the holding unit 18 of the unloading and loading robot 8 may vary after the workpiece 11 separated from the holding unit 18 has been held again by the holding unit 18.

Therefore, the image capturing unit 19 may capture not only an image for use in determining whether foreign matter is attached to the face side 11a of the workpiece 11 or not, but also an image for use in grasping the position of the notch 11c or orientation flat. In a case where the image capturing unit 19 captures an image for use in grasping the position of the notch 11c or orientation flat, the on-delivery deviation referred to above may be grasped on the basis of the image thus captured.

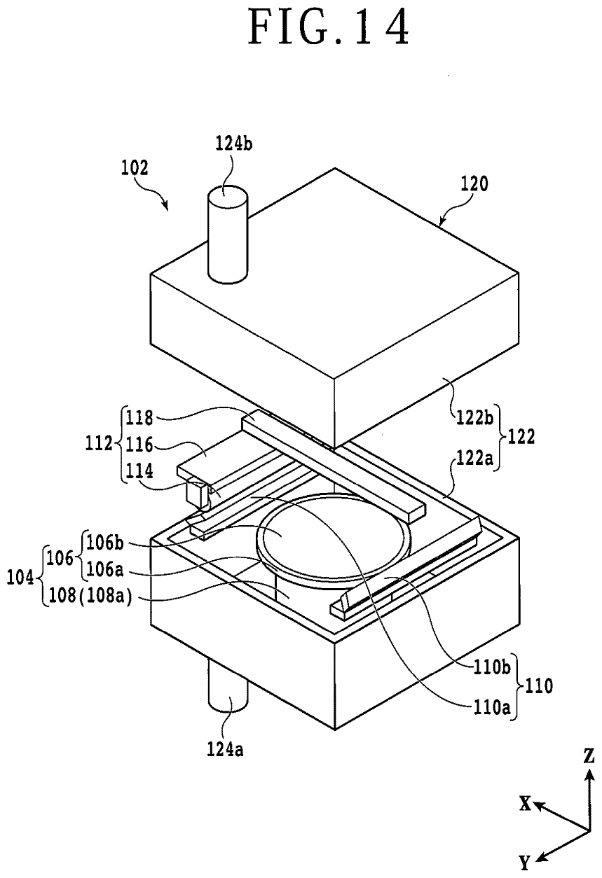

FIG. 14 schematically illustrates the fixing unit 102 in perspective. In FIG. 14, the fixing unit 102 is illustrated in reference to a three-dimensional coordinate system having an X-direction, a Y-direction, and a Z-direction that are the same as the X-direction, the Y-direction, and the Z-direction illustrated in FIG. 8 and other figures. The fixing unit 102 is in a position spaced in the Y-direction from the image capturing unit 100 of the preparing unit 36.

### <(a) First Holding Unit>

As illustrated in FIG. 14, the fixing unit 102 includes a first holding unit 104 for holding the workpiece 11 thereon. The first holding unit 104 includes a disk-shaped chuck table 106. Specifically, the chuck table 106 has a disk-shaped frame 106a made of ceramic, for example. The frame 106a includes a disk-shaped bottom wall and a hollow cylindrical side wall extending upwardly from an outer edge of the bottom wall.

The frame 106a has a circular recess defined in its upper surface by the bottom wall and the side wall. A disk-shaped porous plate 106b made of porous ceramic, for example, is fixedly fitted in the circular recess. The upper surface of the frame 106a and the upper surface of the porous plate 106b lie flush with each other and jointly provide a holding surface of the chuck table 106. The inside diameter of the side wall of the frame 106a is slightly smaller than the diameter of the face side 11a of the workpiece 11. The outside diameter of the side wall of the frame 106a, i.e., the diameter of the holding surface of the chuck table 106, is slightly larger than the diameter of the face side 11a of the workpiece 11 and smaller than the lengths in the X-direction and the Y-direction of the individual sheet 27.

The frame 106a has a fluid channel defined therein that is fluidly connected to the porous plate 106b and that is fluidly connectable selectively to a suction source, not depicted, and an air supply source, not depicted. The suction source includes an ejector, for example. The air supply source includes a tank for storing air, a filter for removing foreign matter contained in the air supplied from the tank, and a regulator for regulating the pressure of the air supplied from the tank, for example.

When the suction source is fluidly connected to the fluid channel in the frame 106a and actuated, it develops a negative pressure in the fluid channel and hence the porous plate 106b, thereby generating a suction force in a space near the upper surface of the porous plate 106b. When the suction source connected to the fluid channel in the frame 106a is turned off and disconnected from the fluid channel and the air supply source is fluidly connected to the fluid channel and actuated, the air supply source supplies air to the fluid channel, bringing the atmospheric pressure back in the fluid channel. Therefore, the suction force that has been generated in the space near the upper surface of the porous plate 106b is eliminated.

The chuck table 106 is coupled to a rotating mechanism 108 for rotating the chuck table 106 about its vertical central axis. The rotating mechanism 108 includes a vertical shaft 108a supporting the chuck table 106 on its upper end, a pulley, not depicted, coaxially mounted on the shaft 108a, and an electric motor, not depicted, for rotating the pulley through an endless belt trained around the pulley and the output shaft of the electric motor.

For introducing the workpiece 11 into the fixing unit 102, the other surface 18b of the holding unit 18 holds the workpiece 11 such that the reverse side 11b of the workpiece 11 is exposed and the face side 11a thereof faces downwardly, and the unloading and loading robot 8 is actuated to position the workpiece 11 over the chuck table 106. In a case where the on-delivery deviation referred to above has been grasped, the unloading and loading robot 8 should preferably be actuated to position the center of the workpiece 11 directly above the center of the chuck table 106 in view of the on-delivery deviation.

Then, the unloading and loading robot 8 is actuated to lower the workpiece 11 until the reverse side 11b contacts the upper surface, i.e., the holding surface, of the chuck table 106. Then, the unloading and loading robot 8 is actuated to separate the workpiece 11 from the holding unit 18.

Thereafter, the suction source is fluidly connected to the fluid channel in the frame 106a and actuated. Then, the unloading and loading robot 8 is actuated to place the holding unit 18 in a position that does not overlie the chuck table 106.

As described above, the image capturing unit 19 may capture an image for use in grasping the position of the notch 11c or orientation flat in the workpiece 11. When the image capturing unit 19 captures such an image, the orientation of the workpiece 11 held on the holding surface of the chuck table 106 may be adjusted on the basis of the captured image.

In this case, specifically, the rotating mechanism 108 may be actuated to turn the chuck table 106 about its vertical central axis to position the notch 11c or orientation flat in a predetermined direction from the center of the workpiece 11 as viewed in plan.

### <(b) Second Holding Unit>

A second holding unit 110 for holding the individual sheet 27 is disposed around the chuck table 106. The second holding unit 110 includes a pair of clamps 110a and 110b extending along the Y-direction and having respective lengths essentially equal to the length of the individual sheet 27 along the Y-direction.

The clamps 110a and 110b are spaced apart from each other by a distance slightly smaller than the length along the X-direction of the individual sheet 27 and face each other along the X-direction across the chuck table 106 as viewed in plan. The clamp 110a is slightly lower in position than the clamp 110b. In other words, the clamp 110a is positioned obliquely downwardly of the clamp 110b.

For introducing the individual sheet 27 into the fixing unit 102, the feeding unit 98 of the preparing unit 36 is actuated to position the holding plate 50 in the transferring position while the holding plate 50 is holding the individual sheet 27 such that the to-be-fixed region 27a is exposed and faces downwardly. The transferring position is slightly higher than the clamps 110a and 110b. For positioning the holding plate 50 in the transferring position, the Z-direction moving mechanism 54 of the preparing unit 36 may be actuated to adjust the position of the holding plate 50 along the Z-direction.

Then, the clamp 110a is actuated to grip the end in the X-direction of a layered structure of the excess region 27b of the individual sheet 27 and the protective sheet 25 that is sagging from the surface 50a of the holding plate 50, and the clamp 110b is actuated to grip the other end of the layered structure of the excess region 27b of the individual sheet 27 and the protective sheet 25. Then, the suction source connected to the suction holes 50c in the four corners of the surface 50a of the holding plate 50 is turned off and disconnected from the suction holes 50c and the air supply source is connected to the suction holes 50c and actuated.

The atmospheric pressure is now brought back in the suction holes 50c, releasing the layered structure of the excess region 27b of the individual sheet 27 and the protective sheet 25 from the surface 50a of the holding plate 50, whereupon the layered structure of the excess region 27b of the individual sheet 27 and the protective sheet 25 is separated from the holding plate 50 due to gravity. As a result, the layered structure of the excess region 27b of the individual sheet 27 and the protective sheet 25 is transferred to the clamps 110a and 110b. After the completion of the transfer to the clamps 110a and 110b, the feeding unit 98 of the preparing unit 36 is actuated to place the holding plate 50 in the processing position.

### <(c) Pressing Unit and Depressurizing Unit>

A pressing unit 112 for pressing the to-be-fixed region 27a of the individual sheet 27 toward the face side 11a of the workpiece 11 is disposed above the chuck table 106 and the clamps 110a and 110b. The pressing unit 112 includes a roller 114 extending along the Y-direction and having a length essentially equal to the length along the Y-direction of the layered structure of the excess region 27b of the individual sheet 27 and the protective sheet 25.

The roller 114 is supported by a support 116 such that the roller 114 has its lower end exposed and is able to roll about its longitudinal central axis. The support 116 is coupled to an X-direction and Z-direction moving mechanism 118. In FIG. 14, the X-direction and Z-direction moving mechanism 118 is illustrated as a block shaped as a rectangular parallelepiped extending along the X-direction for illustrative purposes.

The X-direction and Z-direction moving mechanism 118 includes an actuator such as an air cylinder, for example, for selectively lifting and lowering the roller 114 and the support 116, an X-direction support plate secured to an upper side of the actuator, a ball screw for moving the support plate along the X-direction, and an electric motor for rotating a screw shaft of the ball screw about its longitudinal central axis.

When the electric motor is energized, it rotates the screw shaft, causing the X-direction support plate and hence the actuator, the roller 114, and the support 116 to move along the X-direction. When the actuator is operated to lower the roller 114 and the support 116 that are positioned above the chuck table 106, the roller 114 and the support 116 are lowered until the roller 114 is pressed against the chuck table 106.

The fixing unit 102 also includes a depressurizing unit 120 for depressurizing a space to a pressure lower than the atmospheric pressure when the to-be-fixed region 27a of the individual sheet 27 is fixed to the face side 11a of the workpiece 11 in the space. The depressurizing unit 120 has a chamber 122 for accommodating therein the chuck table 106, the clamps 110a and 110b, the roller 114, the support 116, and the X-direction and Z-direction moving mechanism 118.

The chamber 122 includes a lower chamber 122a shaped as a square tube including a rectangular bottom wall. The lower chamber 122a includes side walls extending upwardly from the outer edges of the bottom wall and having respective upper ends positioned below the holding surface of the chuck table 106. The bottom wall of the lower chamber 122a has an opening defined therein. The vertical shaft 108a has a lower end rotatably disposed in the opening with a bearing, not depicted, interposed therebetween.

A vertical pipe 124a is connected to a corner of the bottom wall of the lower chamber 122a. The pipe 124a is fluidly connected to a lower chamber pump, not depicted, through a lower chamber first valve, not depicted, and is open into a space around the chamber 122, i.e., a space where the atmospheric pressure exists, through a lower chamber second valve, not depicted. In FIG. 14, the pipe 124a is illustrated as a cylindrical shape for illustrative purposes.

The chamber 122 further includes an upper chamber 122b shaped as a square tube including a rectangular top wall. The upper chamber 122b includes side walls extending downwardly from the outer edges of the top wall and having respective lower ends facing the respective upper ends of the side walls of the lower chamber 122a.

A vertical pipe 124b is connected to a corner of the top wall of the upper chamber 122b. The pipe 124b is fluidly connected to an upper chamber pump, not depicted, through an upper chamber first valve, not depicted, and is open into the space around the chamber 122 through an upper chamber second valve, not depicted. In FIG. 14, the pipe 124b is illustrated as a cylindrical shape for illustrative purposes.

The upper chamber 122b is coupled to a Z-direction moving mechanism, not depicted. The Z-direction moving mechanism includes an actuator such as an air cylinder capable of moving the upper chamber 122b along the Z-direction. When the actuator is operated, it moves the upper chamber 122b along the Z-direction between an accommodating position and an exposing position.

The accommodating position refers to a position where the side walls of the upper chamber 122b are held in intimate contact with the side walls of the lower chamber 122a to accommodate the chuck table 106, the clamps 110a and 110b, the roller 114, the support 116, and the X-direction and Z-direction moving mechanism 118 in the chamber 122. The exposing position refers to a position where the side walls of the upper chamber 122b are spaced upwardly from the side walls of the lower chamber 122a to expose the chuck table 106, the clamps 110a and 110b, the roller 114, the support 116, and the X-direction and Z-direction moving mechanism 118 between the lower chamber 122a and the upper chamber 122b, rather than accommodating them in the chamber 122.

For fixing the to-be-fixed region 27a of the individual sheet 27 to the face side 11a of the workpiece 11 using the pressing unit 112, the Z-direction moving mechanism coupled to the upper chamber 122b is actuated to place the upper chamber 122b in the accommodating position. The workpiece 11 held on the holding surface of the chuck table 106 with the face side 11a exposed and facing upwardly and the individual sheet 27 whose both ends in the X-direction are gripped respectively by the clamps 110a and 110b with the to-be-fixed region 27a exposed and facing downwardly are now accommodated in the chamber 122.

Then, in order to have an internal space defined in the chamber 122, the lower chamber first valve and the upper chamber first valve are opened and the lower chamber second valve and the upper chamber second valve are close. Then, in order to depressurize the internal space in the chamber 122 to a pressure lower than the atmospheric pressure, the lower chamber pump fluidly connected to the pipe 124a through the lower chamber first valve is actuated and the upper chamber pump fluidly connected to the pipe 124b through the upper chamber first valve is actuated.

Then, the X-direction and Z-direction moving mechanism 118 is actuated to position the roller 114 directly above the center in the X-direction of the workpiece 11 held on the chuck table 106 with the individual sheet 27 interposed therebetween. Then, the X-direction and Z-direction moving mechanism 118 is actuated to lower the roller 114 until the individual sheet 27 is sandwiched by the workpiece 11 and the roller 114. Thus, the individual sheet 27 is pressed against the workpiece 11 held on the holding surface of the chuck table 106.

Thereafter, the X-direction and Z-direction moving mechanism 118 is actuated to move the roller 114 until the roller 114 reaches a position over the end of the chuck table 106 closest to the clamp 110a while pressing the individual sheet 27 against the workpiece 11. In this manner, a portion, i.e., a side portion, of the to-be-fixed region 27a of the individual sheet 27 that extends from the center to the end thereof in the X-direction is affixed to the face side 11a of the workpiece 11.

Then, the X-direction and Z-direction moving mechanism 118 is actuated to move the roller 114 until the roller 114 reaches a position over the opposite end of the chuck table 106 closest to the clamp 110b while pressing the individual sheet 27 against the workpiece 11. In this manner, a portion, i.e., another side portion, of the to-be-fixed region 27a of the individual sheet 27 that extends from the center to the opposite end thereof in the X-direction is affixed to the face side 11a of the workpiece 11.

Upon completion of the affixing of the to-be-fixed region 27a of the individual sheet 27 to the face side 11a of the workpiece 11, the pressing unit 112 and the depressurizing unit 120 are returned to their original conditions. Specifically, the X-direction and Z-direction moving mechanism 118 is actuated to space the roller 114 away from the individual sheet 27, after which the atmospheric pressure is brought back in the internal space in the chamber 122.

More specifically, the lower chamber pump and the upper chamber pump are turned off, and the lower chamber first valve and the upper chamber first valve are closed and then the lower chamber second valve and the upper chamber second valve area opened. Then, the Z-direction moving mechanism coupled to the upper chamber 122b is actuated to place the upper chamber 122b in the exposing position.

The to-be-fixed region 27a of the individual sheet 27 is fixed to the face side 11a of the workpiece 11 by the fixing unit 102 within the chamber 122 that has been depressurized to a pressure lower than the atmospheric pressure. Therefore, the probability that air bubbles will be trapped between to-be-fixed region 27a of the individual sheet 27 and the face side 11a of the workpiece 11 is reduced.

In the fixing unit 102, the clamp 110a of the second holding unit 110 is slightly lower in position than the clamp 110b. Therefore, when the side portion of the to-be-fixed region 27a of the individual sheet 27 is to be fixed to the face side 11a of the workpiece 11, the probability that areas included in the other side portion of the to-be-fixed region 27a will be fixed to the face side 11a of the workpiece 11 is reduced. Specifically, the probability that the to-be-fixed region 27a of the individual sheet 27 will be fixed as it is bent to the face side 11a of the workpiece 11 is reduced.

### <(7) Removing Unit>

The workpiece 11 with the to-be-fixed region 27a fixed to the face side 11a thereof (hereinafter referred to simply as “the workpiece 11 with the individual sheet 27 fixed thereto”) is delivered to a removing unit 126 (see FIG. 2) for removing the excess region 27b from the individual sheet 27.

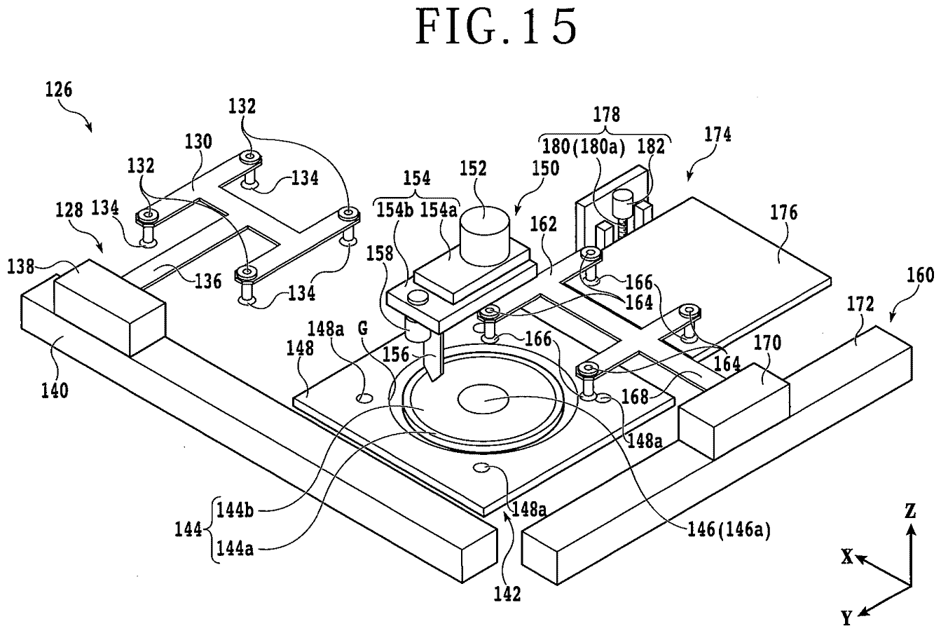

FIG. 15 schematically illustrates the removing unit 126 in perspective. In FIG. 15, the removing unit 126 is illustrated in reference to a three-dimensional coordinate system having an X-direction, a Y-direction, and a Z-direction that are the same as the X-direction, the Y-direction, and the Z-direction illustrated in FIG. 8 and other figures. The removing unit 126 have their major components in a position spaced from the fixing unit 102 in a direction opposite the X-direction.

### <(a) First Feeding Unit>

As illustrated in FIG. 8, the removing unit 126 includes a first feeding unit 128 for unloading the workpiece 11 with the individual sheet 27 fixed thereto from the fixing unit 102. The first feeding unit 128 has a support plate 130 that is H-shaped as viewed in plan.

The support plate 130 has a length in the X-direction that is smaller than the distance in the X-direction between the clamps 110a and 110b of the fixing unit 102. The support plate 130 has a length in the Y-direction that is slightly smaller than the length in the Y-direction of the individual sheet 27.

The support plate 130 has four ends in which respective fluid tubes 132 are inserted. The fluid tubes 132 have respective lower ends with suction pads 134 mounted thereon. The suction pads 134 are fluidly connectable selectively to a suction source, not depicted, and an air supply source, not depicted, via the fluid tubes 132 and pipes, not depicted.

The suction source includes an ejector, for example. The air supply source includes a tank for storing air, a filter for removing foreign matter contained in the air supplied from the tank, and a regulator for regulating the pressure of the air supplied from the tank, for example.

When the suction source is fluidly connected to the suction pads 134 and actuated, it develops a negative pressure in the fluid tubes 132, generating a suction force in respective spaces near the lower surfaces of the suction pads 134. After the suction source has been turned off, when the air supply source is fluidly connected to the suction pads 134 and actuated, it brings the atmospheric pressure back in the fluid tubes 132, eliminating the suction force.

A support arm 136 extending along the Y-direction has a distal end secured to the support plate 130 at its center. The support arm 136 has a proximal end coupled to a Z-direction moving mechanism 138. The Z-direction moving mechanism 138 includes, for example, an actuator such as an air cylinder capable of selectively lifting and lowering the support arm 136.

When the Z-direction moving mechanism 138 is actuated, it lifts or lowers the support arm 136 and hence the four suction pads 134 of the first feeding unit 128. The Z-direction moving mechanism 138 is coupled to an X-direction moving mechanism 140. In FIG. 15, the X-direction moving mechanism 140 is illustrated as a block shaped as a rectangular parallelepiped extending along the X-direction for illustrative purposes.

The X-direction moving mechanism 140 includes a support plate secured to a lower side of the Z-direction moving mechanism 138, a ball screw for moving the support plate along the X-direction, and an electric motor for rotating a screw shaft of the ball screw about its longitudinal central axis, for example. When the X-direction moving mechanism 140 is actuated, it moves the four suction pads 134 along the X-direction between an unloading position and a loading position.

Specifically, the unloading position refers to a position where the four suction pads 134 lie entirely over the individual sheet 27 in the Z-direction whose both ends in the X-direction are gripped by the clamps 110a and 110b of the fixing unit 102. The loading position refers to a position where the four suction pads 134 lie entirely over a holding plate 148 of a holding unit 142 in the Z-direction as described later.

For unloading the workpiece 11 with the individual sheet 27 fixed thereto from the fixing unit 102, the Z-direction moving mechanism 138 is actuated to position the lower surfaces of the four suction pads 134 above the individual sheet 27. Then, the X-direction moving mechanism 140 is actuated to place the four suction pads 134 in the unloading position.

Thereafter, the suction source is fluidly connected to the suction pads 134 and actuated to cause the suction pads 134 to hold the individual sheet 27 on their lower surfaces. Then, the fixing unit 102 is actuated to cause the clamps 110a and 110b to release the both ends of the individual sheet 27 in the X-direction and also to cause the chuck table 106 to release the workpiece 11.

Then, the Z-direction moving mechanism 138 is actuated to lift the four suction pads 134 and also the workpiece 11 and the individual sheet 27 until both the workpiece 11 and the individual sheet 27 are positioned above the clamps 110a and 110b. Then, the X-direction moving mechanism 140 is actuated to position the four suction pads 134 in the loading position. In this manner, the workpiece 11 with the individual sheet 27 fixed thereto is unloaded from the fixing unit 102.

### <(b) Holding Unit>

A holding unit 142 for holding the workpiece 11 with the individual sheet 27 fixed thereto is disposed in a position spaced from the fixing unit 102 in a direction opposite the X-direction. The holding unit 142 includes a disk-shaped chuck table 144. Specifically, the chuck table 144 includes a disk-shaped frame 144a made of ceramic, for example.

The frame 144a includes a disk-shaped bottom wall and a hollow cylindrical side wall extending upwardly from an outer edge of the bottom wall. The frame 144a has a circular recess defined in its upper surface by the bottom wall and the side wall. The outside diameter of the side wall of the frame 144a is smaller than the diameters of the face side 11a of the workpiece 11 and the reverse side 11b thereof.

A disk-shaped porous plate 144b made of porous ceramic, for example, is fixedly fitted in the circular recess. The upper surface of the frame 144a and the upper surface of the porous plate 144b lie flush with each other and jointly provide a holding surface of the chuck table 144. The frame 144a and the porous plate 144b have respective through holes defined centrally therein that are circular in shape as viewed in plan. A lifting and lowering mechanism 146 is disposed in the through holes in the frame 144a and the porous plate 144b.

The lifting and lowering mechanism 146 includes an actuator such as an air cylinder, for example, for selectively lifting and lowering a vertical cylindrical rod 146a. When the lifting and lowering mechanism 146 is actuated, it moves the rod 146a vertically between a protrusive position and a level position. The diameter of the rod 146a as viewed in plan is smaller than the distance I (see FIG. 4) between the fingers of the holding unit 18 of the unloading and loading robot 8 described above.

Specifically, the protrusive position refers to a position where the rod 146a has its upper end surface protrudes upwardly from the upper surface of the side wall of the frame 144a and the upper surface of the porous plate 144b, i.e., the holding surface of the chuck table 144. The level position refers to a position where the upper end surface of the rod 146a lies flush with the holding surface of the chuck table 144. When the workpiece 11 with the individual sheet 27 fixed thereto is unloaded from the fixing unit 102 by the first feeding unit 128, the rod 146a is kept in the level position.

A holding plate 148 is disposed around the chuck table 144. The holding plate 148 has a circular through hole defined centrally therein that is larger in diameter than the diameters of the face side 11a of the workpiece 11 and the reverse side 11b thereof. The chuck table 144 is disposed within the through hole with a predetermined gap G being present around the chuck table 144.

The holding plate 148 has four suction holes 148a defined in its upper surface that are angularly spaced by substantially equal angular intervals around the center of the rod 146a of the lifting and lowering mechanism 146 as viewed in plan. The number of the suction holes 148a is not limited to four. Generally, the holding plate 148 may have as many angularly spaced suction holes 148a defined in its upper surface as (4×k) (k represents a natural number of 2 or more) at essentially equal angles around the center of the rod 146a as viewed in plan.

The frame 144a further has a fluid channel defined therein separately from the through hole in which the lifting and lowering mechanism 146 is disposed. The fluid channel and the suction holes 148a are fluidly connectable selectively to a suction source, not depicted, and an air supply source, not depicted. The suction source includes an ejector, for example. The air supply source includes a tank for storing air, a filter for removing foreign matter contained in the air supplied from the tank, and a regulator for regulating the pressure of the air supplied from the tank, for example.

When the suction source is fluidly connected to the fluid channel and the suction holes 148a and actuated, it develops a negative pressure in the fluid channel and the suction holes 148a, thereby generating a suction force in spaces near the suction holes 148a. When the suction source is turned off and disconnected from the fluid channel and the suction holes 148a and the air supply source is connected to the fluid channel and the suction holes 148a and actuated, it brings the atmospheric pressure back in the fluid channel and the suction holes 148a, eliminating the suction force.

The fluid channel and each of the suction holes 148a may be fluidly connectable selectively to different suction sources and different air supply sources. Specifically, the fluid channel may be fluidly connectable selectively to a first suction source and a first air supply source, and each of the suction holes 148a may be fluidly connectable selectively to a second suction source different from the first suction source and a second air supply source different from the first air supply source. With this alternative, a suction force may be caused to act selectively in the space near the upper surface of the porous plate 144b and the space near each of the suction holes 148a and may selectively be eliminated.

In addition, the chuck table 144, the lifting and lowering mechanism 146, and the holding plate 148 are coupled to an X-direction and Y-direction moving mechanism, not depicted. The X-direction and Y-direction moving mechanism includes, for example, an X-direction support plate fixed to a lower side of each of the chuck table 144, the lifting and lowering mechanism 146, and the holding plate 148, a ball screw for moving the X-direction support plate along the X-direction, and an X-direction electric motor for rotating a screw shaft of the X-direction ball screw about its longitudinal central axis. When the X-direction electric motor is energized, it rotates the screw shaft, causing the X-direction support plate and hence the chuck table 144, the lifting and lowering mechanism 146, and the holding plate 148 to move along the X-direction.

The X-direction and Y-direction moving mechanism further includes, for example, a Y-direction support plate secured to the X-direction ball screw and the Y-direction electric motor, a ball screw for moving the Y-direction support plate along the Y-direction, and a Y-direction electric motor for rotating a screw shaft of the Y-direction ball screw about its longitudinal central axis. When the Y-direction electric motor is energized, it rotates the screw shaft, causing the Y-direction support plate and hence the chuck table 144, the lifting and lowering mechanism 146, and the holding plate 148 to move along the Y-direction.

When the workpiece 11 with the individual sheet 27 fixed thereto is unloaded from the fixing unit 102 by the first feeding unit 128, the individual sheet 27 and the workpiece 11 are held by the holding unit 142. Specifically, the Z-direction moving mechanism 138 is actuated to lower the four suction pads 134 placed in the loading position until the workpiece 11 contacts the holding surface of the chuck table 144.

Then, the suction source fluidly connected to the suction pads 134 is turned off and disconnected therefrom and the air supply source is fluidly connected to the suction pads 134 and actuated. The atmospheric pressure is now brought back in the fluid tubes 132, whereupon the layered structure of the excess region 27b of the individual sheet 27 and the protective sheet 25 from the suction pads 134 is no longer attracted under suction to the suction pads 134 and is separated from the suction pads 134 due to gravity. As a result, the layered structure is placed onto the holding plate 148.

Then, the suction source is fluidly connected to the fluid channel in the frame 144a of the chuck table 144 and the suction holes 148a in the upper surface of the holding plate 148 and actuated. The workpiece 11 and the to-be-fixed region 27a of the individual sheet 27 are held under suction on the holding surface of the chuck table 144, and the layered structure of the excess region 27b of the individual sheet 27 and the protective sheet 25 is held under suction mainly on the upper surface of the holding plate 148.

### <(c) Cutting Unit>

A cutting unit 150 for cutting the individual sheet 27 to separate the to-be-fixed region 27a and the excess region 27b from each other is disposed above the holding unit 142. The cutting unit 150 includes a vertical shaft 152 whose center is positioned immediately above the center of the rod 146a of the lifting and lowering mechanism 146 in alignment therewith.

The shaft 152 has an upper end coupled to an electric motor, not depicted, for rotating the shaft 152 about its vertical central axis along the Z-direction. The shaft 152 has a lower end coupled to a radial-direction moving mechanism 154 extending in a direction (herein after referred to “radial direction”) normal to the Z-direction.

The radial-direction moving mechanism 154 includes, for example, a case 154a having a proximal end whose upper surface is secured to the lower end of the shaft 152, a ball screw, not depicted, housed in the case 154a and an electric motor, not depicted, housed in the case 154a for rotating a screw shaft of the ball screw about its longitudinal central axis, and a support plate 154b having a proximal end whose upper surface is secured to a nut of the ball screw.

The support plate 154b supports on its distal end a cutter 156 having a pointed cutting edge directed downwardly and a camera 158 for capturing an image of an area beneath itself using light, e.g., infrared rays, transmittable through the individual sheet 27. The cutter 156 and the camera 158 are disposed adjacent to each other in the radial direction.

When the electric motor housed in the case 154a is energized, it moves the support plate 154b and hence the cutter 156 and the camera 158 along the radial direction within a range in which the pointed cutting edge of the cutter 156 is positioned directly above the gap G between the chuck table 144 and the holding plate 148 as viewed in plan.

The shaft 152 is coupled to a Z-direction moving mechanism, not depicted. The Z-direction moving mechanism includes, for example, an actuator, not depicted, such as an air cylinder capable of selectively lifting and lowering the shaft 152. When the Z-direction moving mechanism is actuated, it moves the cutter 156 along the Z-direction between a cutting position and a standby position.

Specifically, the cutting position refers to a position where the pointed cutting edge of the cutter 156 is positioned in the gap G between the chuck table 144 and the holding plate 148. The standby position refers to a position where the pointed cutting edge of the cutter 156 is positioned above the support plate 130 at the time the four suction pads 134 of the first feeding unit 128 is in the unloading position. When the first feeding unit 128 unloads the workpiece 11 with the individual sheet 27 fixed thereto from the fixing unit 102, the cutter 156 is placed in the standby position.

When the individual sheet 27 and the workpiece 11 are held by the holding unit 142, as described above, the individual sheet 27 is cut to separate the to-be-fixed region 27a and the excess region 27b from each other. Specifically, first, the camera 158 is energized to capture an image of the outer edge of the workpiece 11. For example, while the camera 158 is being energized to capture an image of the workpiece 11, the electric motor coupled to the upper end of the shaft 152 is energized to cause the camera 158 to make at least one revolution around the vertical central axis of the shaft 152.

Then, on the basis of the image captured by the camera 158, the position of the outer edge of the workpiece 11 is specified, or specifically, its coordinates are specified in a coordinate XY plane having an origin (0, 0) at the vertical central axis of the shaft 152 and extending parallel to the X-direction and the Y-direction. Then, the coordinates (Xc, Yc) of the center of the workpiece 11 in the XY plane are calculated by referring to the coordinates in the XY plane of at least three points included in the outer edge of the workpiece 11.

Then, the X-direction and Y-direction moving mechanism of the holding unit 142 is actuated to bring the center of the workpiece 11 into alignment with the vertical central axis of the shaft 152. Specifically, the X-direction and Y-direction moving mechanism is actuated to move the chuck table 144 and the holding plate 148 by −Xc along the X-direction and by −Yc along the Y-direction.

Then, the radial-direction moving mechanism 154 is actuated to make the distance between the vertical central axis of the shaft 152 and the lower end of the pointed cutting edge of the cutter 156 equal to the radius of the to-be-fixed region 27a of the individual sheet 27. The radius of the to-be-fixed region 27a of the individual sheet 27 represents the radius of a circle along the outer edge of the workpiece 11 except the notch 11c or orientation flat, or a value obtained by adding a predetermined offset to the radius of the circle.

Then, the Z-direction moving mechanism coupled to the shaft 152 is actuated to bring the cutter 156 into the cutting position. Thereafter, the electric motor coupled to the upper end of the shaft 152 is energized to cause the cutter 156 to make at least one revolution around the vertical central axis of the shaft 152, thereby cutting the individual sheet 27 along the boundary between the to-be-fixed region 27a and the excess region 27b with the pointed cutting edge moving along the gap G.

Specifically, the cutter 156 separates the workpiece 11 and the to-be-fixed region 27a of the individual sheet 27 that are held on the holding surface of the chuck table 106 (hereinafter referred to as “the workpiece 11 with the sheet fixed thereto”) and the layered structure of the excess region 27b of the individual sheet 27 and the protective sheet 25 that are held on the upper surface of the holding plate 148 (hereinafter referred to as “redundant sheet”) from each other. Upon completion of the separation, the holding unit 142 and the cutting unit 150 are returned to their original positions.

Specifically, the Z-direction moving mechanism coupled to the shaft 152 is actuated to bring the cutter 156 into the standby position. Then, the suction source fluidly connected to the fluid channel in the frame 144a of the chuck table 144 and the suction holes 148a in the upper surface of the holding plate 148 is turned off and disconnected, and the air supply source is fluidly connected to the fluid channel and the suction holes 148a and actuated. The workpiece 11 with the sheet fixed thereto is now simply placed on the holding surface of the chuck table 144, and the redundant sheet is simply placed on the upper surface of the holding plate 148.

The cutting unit 150 cuts the individual sheet 27 to separate the to-be-fixed region 27a and the excess region 27b from each other after the position of the outer edge of the workpiece 11 has been specified on the basis of the image captured by the camera 158. Even if the position of the workpiece 11 held by the holding unit 142 deviates from a desired position, e.g., even if the center of the workpiece 11 in the XY plane is positioned out of alignment with the vertical central axis of the shaft 152, the individual sheet 27 can accurately be cut along the boundary between the to-be-fixed region 27a and the excess region 27b by the cutting unit 150.

### <(d) Second Feeding Unit and Retrieving Unit>

A second feeding unit 160 for unloading the redundant sheet from the holding unit 142 is disposed in the vicinity of the holding unit 142. The second feeding unit 160 is of a structure similar to the first feeding unit 128 except that the second feeding unit 160 is oriented in a different direction from the first feeding unit 128. Specifically, the second feeding unit 160 includes a support plate 162 that is similar in shape to the support plate 130.

The support plate 162 has four ends in which respective fluid tubes 164 are inserted. The fluid tubes 164 have respective lower ends with suction pads 166 mounted thereon. The suction pads 166 are fluidly connectable selectively to a suction source, not depicted, and an air supply source, not depicted, via the fluid tubes 164 and pipes, not depicted.

The suction source includes an ejector, for example. The air supply source includes a tank for storing air, a filter for removing foreign matter contained in the air supplied from the tank, and a regulator for regulating the pressure of the air supplied from the tank, for example.

When the suction source is fluidly connected to the suction pads 166 and actuated, it develops a negative pressure in the fluid tubes 164, generating a suction force in respective spaces near the lower surfaces of the suction pads 166. After the suction source has been turned off, when the air supply source is fluidly connected to the suction pads 166 and actuated, it brings the atmospheric pressure back in the fluid tubes 164, eliminating the suction force.

A support arm 168 extending along the X-direction has a distal end secured to the support plate 162 at its center. The support arm 168 has a proximal end coupled to a Z-direction moving mechanism 170. The Z-direction moving mechanism 170 includes, for example, an actuator such as an air cylinder capable of selectively lifting and lowering the support arm 168.

When the Z-direction moving mechanism 170 is actuated, it lifts or lowers the support arm 168 and hence the four suction pads 166 of the second feeding unit 160. The Z-direction moving mechanism 170 is coupled to a Y-direction moving mechanism 172. In FIG. 15, the Y-direction moving mechanism 172 is illustrated as a block shaped as a rectangular parallelepiped extending along the Y-direction for illustrative purposes.

The Y-direction moving mechanism 172 includes a support plate secured to a lower side of the Z-direction moving mechanism 170, a ball screw for moving the support plate along the Y-direction, and an electric motor for rotating a screw shaft of the ball screw about its longitudinal central axis, for example. When the Y-direction moving mechanism 172 is actuated, it moves the four suction pads 166 along the Y-direction between a retrieving position and a discarding position.

Specifically, the retrieving position refers to a position where the four suction pads 166 lie entirely over the redundant sheet in the Z-direction that is placed on the upper surface of the holding plate 148. The discarding position refers to a position where the four suction pads 166 lie entirely over a retrieval base 176 of a retrieving unit 174 for retrieving the redundant sheet.

The retrieving unit 174 is disposed in a position spaced from the holding unit 142 in a direction opposite the X-direction. The retrieving unit 174 includes the retrieval base 176 that is of a rectangular shape whose sides are longer than the sides of the individual sheet 27 as viewed in plan. The retrieval base 176 is coupled to a Z-direction moving mechanism 178.

The Z-direction moving mechanism 178 includes a ball screw 180 for moving the retrieval base 176 along the Z-direction and an electric motor 182 for rotating a screw shaft 180a of the ball screw 180 about its vertical central axis. When the electric motor 182 is energized, it rotates the screw shaft 180a, causing the retrieval base 176 to move along the Z-direction.

After the workpiece 11 with the sheet fixed thereto and the redundant sheet have been separated from each other, the redundant sheet is retrieved by the retrieving unit 174. Specifically, the Y-direction moving mechanism 172 is actuated to bring the four suction pads 166 into the retrieving position. Then, the Z-direction moving mechanism 170 is actuated to lower the four suction pads 166 until they contact the redundant sheet placed on the upper surface of the holding plate 148.

Then, the suction source is fluidly connected to the suction pads 166 and actuated to hold the redundant sheet on the lower surfaces of the suction pads 166. Then, the Z-direction moving mechanism 170 is actuated to lift the redundant sheet. Thereafter, the Y-direction moving mechanism 172 is actuated to bring the four suction pads 166 into the discarding position.

Then, the Z-direction moving mechanism 178 is actuated to position the retrieval base 176 slightly below the redundant sheet. Then, the suction source fluidly connected to the suction pads 166 is turned off and disconnected therefrom, and the air supply source is fluidly connected to the suction pads 166 and actuated.

The atmospheric pressure is brought back in the fluid tubes 164, releasing the redundant sheet from the suction pads 166. The redundant sheet is now separated from the suction pads 166 due to gravity. As a consequence, the redundant sheet is placed onto the retrieval base 176, i.e., is retrieved by the retrieving unit 174.

<(8) Workpiece with Sheet Fixed Thereto>

The workpiece 11 with the sheet fixed thereto is unloaded by the unloading and loading robot 8 (see FIG. 2). For unloading the workpiece 11 with the sheet fixed thereto, the lifting and lowering mechanism 146 of the removing unit 126 is actuated to lift the rod 146a to the protrusive position. The workpiece 11 with the sheet fixed thereto is now lifted off the holding surface of the chuck table 144.

Then, the unloading and loading robot 8 is actuated to position the holding unit 18 with the surface 18a facing upwardly below the workpiece 11 with the sheet fixed thereto and above the chuck table 144. Then, the lifting and lowering mechanism 146 is actuated to lower the rod 146a into the level position. The workpiece 11 with the sheet fixed thereto is now transferred from the rod 146a to the holding unit 18.

Then, the unloading and loading robot 8 is actuated to hold the workpiece 11 with the sheet fixed thereto on the surface 18a of the holding unit 18. Then, the unloading and loading robot 8 is actuated to deliver the workpiece 11 with the sheet fixed thereto toward the image capturing unit 19. Then, the camera 24 of the image capturing unit 19 is energized to capture an image, i.e., a second image, for use in determining whether foreign matter is attached to the sheet fixed to the face side 11a of the workpiece 11 or not.

The second image is captured by the camera 24 of the image capturing unit 19 in the same manner as an image captured for use in determining whether foreign matter is attached to the face side 11a of the workpiece 11 or not. Alternatively, the second image may be captured by a camera, i.e., a second camera, different from the camera 24. In other words, the image capturing unit 19 may include the camera 24, i.e., a first camera, for capturing an image of the face side 11a of the workpiece 11 and a second camera for capturing an image of the sheet fixed to the face side 11a of the workpiece 11.

The second camera is of the same structure as the camera 24. The image capturing unit 19 may include a moving mechanism for moving the oblique lighting devices 22 between a position where the oblique lighting devices 22 face each other with the camera 24 interposed therebetween as viewed in plan and a position where the oblique lighting devices 22 face each other with the second camera interposed therebetween as viewed in plan. In this case, the second image may be captured by the second camera while the light sources 22b of the oblique lighting devices 22 are being energized.

If it is determined that no foreign matter is attached to the sheet on the basis of the second image, then the unloading and loading robot 8 is actuated to deliver the workpiece 11 with the sheet fixed thereto into the cassette 6. The sheet fixing apparatus 2 now has completed its process of fixing a sheet that is commensurate in shape with the face side 11a of the workpiece 11 to the face side 11a.

Conversely, if it is determined that foreign matter is attached to the sheet on the basis of the second image, then the unloading and loading robot 8 is actuated to deliver the workpiece 11 with the sheet fixed thereto to the foreign matter removing unit 26. Then, the foreign matter removing unit 26 is actuated to remove the foreign matter from the sheet fixed to the face side 11a of the workpiece 11. The foreign matter attached to the sheet can be removed by the foreign matter removing unit 26 in the same manner as it is actuated to remove foreign matter from the face side 11a of the workpiece 11, for example.

Then, the unloading and loading robot 8 is actuated to deliver the workpiece 11 with the sheet fixed thereto again to the image capturing unit 19. Then, the camera 24 of the image capturing unit 19 is energized to capture again an image for use in determining whether foreign matter is attached to the sheet fixed to the face side 11a of the workpiece 11 or not.

If the decision is changed on the basis of the captured image, i.e., if it is determined that no foreign matter is attached to the sheet fixed to the face side 11a of the workpiece 11, then the unloading and loading robot 8 is actuated to put the workpiece 11 with the sheet fixed thereto into the cassette 6. The sheet fixing apparatus 2 now has completed its process of fixing a sheet that is commensurate in shape with the face side 11a of the workpiece 11 to the face side 11a.

Conversely, if the decision is not changed on the basis of the captured image, i.e., if it is determined that foreign matter is attached to the sheet fixed to the face side 11a of the workpiece 11, then the unloading and loading robot 8, the image capturing unit 19, and the foreign matter removing unit 26 are actuated to repeat the removal of foreign matter from the sheet fixed to face side 11a of the workpiece 11 and the determination as to whether foreign matter is attached to the sheet or not alternately a predetermined number of times.

In a case where the removal of the foreign matter from the sheet is repeated in a plurality of cycles, operating conditions for the foreign matter removing unit 26 may be changed in each cycle. Specifically, operating conditions in a succeeding cycle, e.g., the flow rate and/or the pressure of the fluid ejected from the nozzle 34a of the fluid ejecting mechanism 34, may be set to a value or values for better removal of the foreign matter from the sheet, e.g., to a higher level or levels, than operating conditions in a preceding cycle.

If the decision is changed during one of the repeated cycles, then the unloading and loading robot 8 is actuated to deliver the workpiece 11 with the sheet fixed thereto into the cassette 6. As a result, the sheet fixing apparatus 2 now has completed its process of fixing a sheet that is commensurate in shape with the face side 11a of the workpiece 11 to the face side 11a.

### <(9) Other Components>

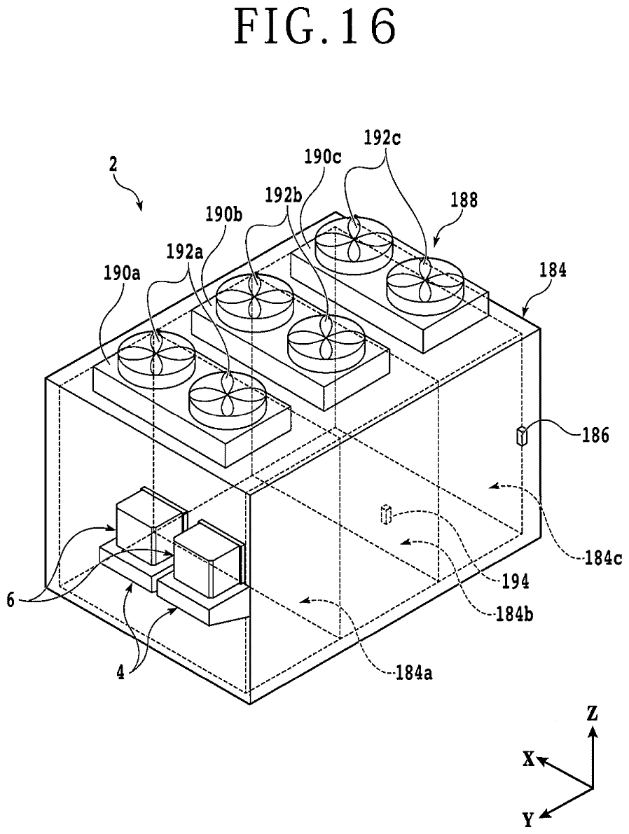

FIG. 16 schematically illustrates an appearance of the sheet fixing apparatus 2. In FIG. 16, the sheet fixing apparatus 2 is illustrated in reference to a three-dimensional coordinate system having an X-direction, a Y-direction, and a Z-direction that are the same as the X-direction, the Y-direction, and the Z-direction illustrated in FIG. 8 and other figures.

As illustrated in FIG. 16, the sheet fixing apparatus 2 includes a housing 184 that houses therein almost all of the components thereof described above except the cassette table 4. In FIG. 16, the sheet fixing apparatus 2 includes two cassette tables 4 protruding outwardly from an end wall of the housing 184 at an end thereof in the Y-direction and supporting respective cassettes 6 thereon. The housing 184 has three spaces or compartments 184a, 184b, and 184c defined therein that are arrayed along the Y-direction and held in fluid communication with each other.

Of the three compartments 184a, 184b, and 184c, the compartment 184a that is closest to the cassette tables 4 houses therein the unloading and loading robot 8, the image capturing unit 19, and the foreign matter removing unit 26, for example. The compartment 184c that is remotest from the cassette tables 4 houses therein the preparing unit 36, for example. The compartment 184b between the compartments 184a and 184c houses therein the fixing unit 102 and the removing unit 126, for example.

The housing 184 has a handle 186 mounted on a side wall facing in a direction opposite the X-direction at a position near the compartment 184c. The handle 186 may be gripped and pulled by the operator to open the side wall for installing or replacing the stock roll 21 of sheet in the preparing unit 36.

The housing 184 supports on its ceiling panel a fan unit 188 for developing downflows of air in the housing 184. The fan unit 188 includes three filters, e.g., high-efficiency particulate air (HEPA) filters or ultra-low penetration air (ULPA) filters, 190a, 190b, and 190c and three pairs of fans 192a, 192b, and 192c mounted respectively on the filters 190a, 190b, and 190c.

Specifically, the filter 190a and the pair of fans 192a are disposed above the compartment 184a, the filter 190b and the pair of fans 192b are disposed above the compartment 184b, and the filter 190c and the pair of fans 192c are disposed above the compartment 184c.

When the fans 192a, 192b, and 192c are actuated, they generate downflows of air in the respective compartments 184a, 184b, and 184c disposed therebelow through the respective filters 190a, 190b, and 190c. The downflows of air force the foreign matter suspended in the compartments 184a, 184b, and 184c to flow downwardly, thereby reducing the probability that the foreign matter will be attached to the workpieces 11 and/or the individual sheets 27.

The sheet fixing apparatus 2 is liable to let the foreign matter enter the housing 184, particularly the compartment 184c, when the side wall of the housing 184 is opened to install or replace the stock roll 21 of sheet in the compartment 184c. In view of the shortcoming, the three sets of fans 192a, 192b, and 192c may be operated to produce a flow of air directed from the compartment 184a to the compartment 184c.

Specifically, the three sets of fans 192a, 192b, and 192c may be operated to produce a strongest downflow of air in the compartment 184a and a weakest downflow of air in the compartment 184c. With such fan operation settings, even if external foreign matter finds its way into the compartment 184c, the probability that the foreign matter that has entered the compartment 184c will flow into the compartment 184a and be attached to workpieces 11 therein is reduced.

Moreover, a counter 194 for counting fine particles is provided in the housing 184, e.g., the compartment 184c. Such fine particles may act as the foreign matter that can be attached to the workpieces 11 and/or the individual sheets 27, and a count of fine particles represents an index for assessing the level of cleanliness in the housing 184. The sheet fixing apparatus 2 changes operating conditions for the fans 192a, 192b, and 192c depending on the count of fine particles measured by the counter 194.

Specifically, in a case where the count of fine particles measured by the counter 194 exceeds a preset threshold value, i.e., a desired level of cleanliness has not been achieved in the housing 184, the sheet fixing apparatus 2 changes operating conditions for the sets of fans 192a, 192b, and 192c to produce stronger downflows of air in the housing 184. It is thus possible to maintain a desired level of cleanliness in the housing 184.

The housing 184 may have a plurality of counters 194 installed therein. For example, the three compartments 184a, 184b, and 184c may have respective counters 194 installed therein. With the counters 194 disposed respectively in the three compartments 184a, 184b, and 184c, there are established threshold values respectively for the counts of fine particles in the three compartments 184a, 184b, and 184c, i.e., a first threshold value for the count of fine particles in the compartment 184a, a second threshold value for the count of fine particles in the compartment 184b, and a third threshold value for the count of fine particles in the compartment 184c. The sheet fixing apparatus 2 may change operating conditions for the respective sets of fans 192a, 192b, and 192c depending on the counts of fine particles measured by the corresponding counters 194.

Specifically, if the count of fine particles measured by the counter 194 in the compartment 184a is in excess of the first threshold value, then the sheet fixing apparatus 2 may change operating conditions for the pair of fans 192a to produce a strong downflow of air in the compartment 184a. If the count of fine particles measured by the counter 194 in the compartment 184b is in excess of the second threshold value, then the sheet fixing apparatus 2 may change operating conditions for the pair of fans 192b to produce a strong downflow of air in the compartment 184b. If the count of fine particles measured by the counter 194 in the compartment 184c is in excess of the third threshold value, then the sheet fixing apparatus 2 may change operating conditions for the pair of fans 192c to produce a strong downflow of air in the compartment 184c.

A touch panel, not depicted, for use as a user interface is provided on an outer side surface of the housing 184. The touch panel includes, for example, an input unit such as a capacitive touch panel or a resistive touch panel and a display unit such as a liquid crystal display or an organic electro luminescence (EL) display.

### <(10) Controller>

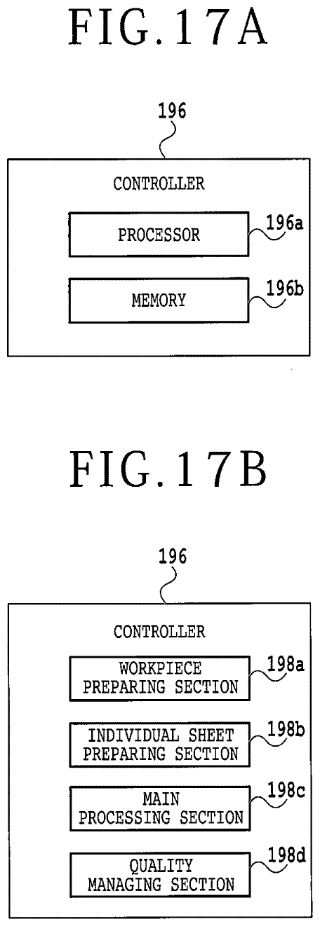

The components of the sheet fixing apparatus 2 are controlled in operation by a controller 196 (see FIG. 2). FIG. 17A schematically illustrates, in block form, an example of the hardware makeup of the controller 196. As illustrated in FIG. 17A, the controller 196 includes a processor 196a and a memory 196b as hardware components.

The processor 196a includes a central processing unit (CPU), for example. The memory 196b includes a volatile memory such as a dynamic random access memory (DRAM) or a static random access memory (SRAM), for example, and a nonvolatile memory such as a solid-state drive (SSD), i.e., a Not AND (NAND)-type flash memory, or a hard-disk drive (HDD), i.e., a magnetic storage device, for example.

The processor 196a can read programs from the memory 196b and execute them to fix a sheet that is commensurate in shape with the face side 11a of the workpiece 11 to the face side 11a, for example. The memory 196b is also able to store, in addition to the programs, data used when the programs are run by the processor 196a, e.g., threshold values to be compared with the counts of fine particles measured by the counters 194.

FIG. 17B schematically illustrates, in block form, functions performed by the controller 196 at the time the sheet fixing apparatus 2 fixes a sheet that is commensurate in shape with the face side 11a of the workpiece 11 to the face side 11a. Specifically, the controller 196 includes a workpiece preparing section 198a, an individual sheet preparing section 198b, a main processing section 198c, and a quality managing section 198d that represent functions performed by the controller 196 at the time of fixing the sheet to the face side 11a of the workpiece 11.

The workpiece preparing section 198a controls the unloading and loading robot 8 and the image capturing unit 19 or the foreign matter removing unit 26 in addition to them in order to prepare a workpiece 11 that is adequate for being fixed to the individual sheet 27. Specifically, the workpiece preparing section 198a first controls the unloading and loading robot 8 and the image capturing unit 19 to capture an image for use in determining whether the foreign matter is attached to the face side 11a of the workpiece 11 or not, and then determines whether the foreign matter is attached to the face side 11a or not on the basis of the captured image.

If the workpiece preparing section 198a determines that no foreign matter is attached to the face side 11a, then the workpiece preparing section 198a controls the unloading and loading robot 8 to load the workpiece 11 into the fixing unit 102. Conversely, if the workpiece preparing section 198a determines that the foreign matter is attached to the face side 11a, then the workpiece preparing section 198a controls the unloading and loading robot 8 and the foreign matter removing unit 26 to remove the foreign matter from the face side 11a, and then determines again whether the foreign matter is attached to the face side 11a or not.

If the decision is changed on the basis of the captured image, i.e., if it is determined that no foreign matter is attached to the face side 11a, then the workpiece preparing section 198a controls the unloading and loading robot 8 to load the workpiece 11 into the fixing unit 102. Conversely, if the decision is not changed on the basis of the captured image, i.e., if it is determined again that the foreign matter is attached to the face side 11a, then the workpiece preparing section 198a controls the unloading and loading robot 8, the image capturing unit 19, and the foreign matter removing unit 26 to repeat the removal of the foreign matter from the face side 11a and the determination as to whether the foreign matter is attached to the face side 11a or not alternately a predetermined number of times.

In a case where the removal of the foreign matter from the face side 11a by the foreign matter removing unit 26 is repeated in a plurality of cycles, operating conditions for the foreign matter removing unit 26 may be changed in each cycle. Specifically, operating conditions in a succeeding cycle, e.g., the flow rate and/or the pressure of the fluid ejected from the nozzle 34a of the fluid ejecting mechanism 34, may be set to a value or values for better removal of the foreign matter from the face side 11a, e.g., to a higher level or levels, than operating conditions in a preceding cycle.

If the decision is changed during one of the repeated cycles, then the workpiece preparing section 198a controls the unloading and loading robot 8 to load the workpiece 11 into the fixing unit 102. Conversely, if the repeated cycles are completed without a change in the decision, then the workpiece preparing section 198a controls the touch panel on the outer side surface of the housing 184 to report to the operator that the workpiece 11 is inadequate for being fixed to the sheet and controls the unloading and loading robot 8 to return the workpiece 11 into the cassette 6.

Moreover, the workpiece preparing section 198a controls the fan unit 188 to establish a suitable level of cleanliness in the housing 184 for preparing a workpiece 11 that is adequate for being fixed to the individual sheet 27, or stated otherwise, for processing a workpiece 11 after it is unloaded from the cassette 6 until it is loaded into the fixing unit 102.

The individual sheet preparing section 198b controls the preparing unit 36 to prepare an individual sheet 27 that is adequate for being fixed to the workpiece 11. Specifically, the individual sheet preparing section 198b controls the withdrawal assembly 38 and the foreign matter removing device 44 to reel out the portion 23a corresponding to an individual sheet from the stock roll 21 of sheet and remove the foreign matter attached to the portion 23a.

Then, the individual sheet preparing section 198b controls the holding unit 48 and the cutting unit 56 to prepare an individual sheet 27 by cutting the portion 23a off the stock roll 21 of sheet. Then, the individual sheet preparing section 198b controls the holding unit 48, the blanking unit 62, and the peeling unit 78 to blank the to-be-peeled-off region 25a out of the protective sheet 25 and then peel off the blanked to-be-peeled-off region 25a from the individual sheet 27.

Then, the individual sheet preparing section 198b controls the holding unit 48, the feeding unit 98, and the image capturing unit 100 to capture an image for use in determining whether the foreign matter is attached to the to-be-fixed region 27a of the individual sheet 27 or not, and determines whether the foreign matter is attached to the to-be-fixed region 27a or not on the basis of the captured image.

If the individual sheet preparing section 198b determines that no foreign matter is attached to the to-be-fixed region 27a, then the individual sheet preparing section 198b controls the holding unit 48 and the feeding unit 98 to load the individual sheet 27 into the fixing unit 102. Conversely, if the individual sheet preparing section 198b determines that the foreign matter is attached to the to-be-fixed region 27a, then the individual sheet preparing section 198b controls the holding unit 48 and the feeding unit 98 to discard the individual sheet 27. After the individual sheet 27 where the foreign matter is attached to the to-be-fixed region 27a thereof has been discarded, the individual sheet preparing section 198b controls the components of the preparing unit 36 to perform the above operation again.

Furthermore, the individual sheet preparing section 198b controls the fan unit 188 to establish a suitable level of cleanliness in the housing 184 for preparing an individual sheet 27 that is adequate for being fixed to the workpiece 11, or stated otherwise, for processing an individual sheet 27 after the portion 23a corresponding to an individual sheet 27 is withdrawn from the stock roll 21 of sheet until it is loaded into the fixing unit 102.

The main processing section 198c controls the fixing unit 102 and the removing unit 126 to fix the workpiece 11 and the individual sheet 27 to each other and then to remove a redundant portion, i.e., the redundant sheet referred to above, of the individual sheet 27. Specifically, first, the main processing section 198c controls the first holding unit 104, the second holding unit 110, the pressing unit 112, and the depressurizing unit 120 to fix the to-be-fixed region 27a of the individual sheet 27 to the face side 11a of the workpiece 11.

Then, the main processing section 198c controls the first holding unit 104, the second holding unit 110, the pressing unit 112, and the depressurizing unit 120, and also the first feeding unit 128 and the holding unit 142 to deliver the workpiece 11 with the individual sheet 27 fixed thereto from the fixing unit 102 to the removing unit 126. Then, after having specified the position of the outer edge of the workpiece 11, the main processing section 198c controls the holding unit 142 and the cutting unit 150 to cut the individual sheet 27 along the boundary between the to-be-fixed region 27a and the excess region 27b by referring to the position of the outer edge of the workpiece 11.

Then, the main processing section 198c controls the holding unit 142, the second feeding unit 160, and the retrieving unit 174 to retrieve the redundant sheet. Thereafter, the main processing section 198c controls the holding unit 142 to make it possible for the unloading and loading robot 8 to unload the workpiece 11 with the sheet fixed thereto from the removing unit 126.

Moreover, the main processing section 198c controls the fan unit 188 to establish a suitable level of cleanliness in the housing 184 for producing a workpiece 11 with a sheet fixed thereto, or stated otherwise, for processing a workpiece 11 and an individual sheet 27 after they have been loaded into the fixing unit 102 until a workpiece 11 with a sheet fixed thereto is unloaded from the removing unit 126.

The quality managing section 198d controls the unloading and loading robot 8 and the image capturing unit 19 or the foreign matter removing unit 26 in addition to them in order to provide a workpiece 11 with a sheet fixed thereto that is adequate for being processed subsequently, e.g., for grinding the reverse side 11b of the workpiece 11 with a grinding apparatus or removing boundaries of a plurality of devices 15 in the workpiece 11 with a cutting apparatus or a laser processing apparatus. Specifically, the quality managing section 198d controls the unloading and loading robot 8 and the image capturing unit 19 to capture an image for use in determining whether the foreign matter is attached to a sheet or not and then determines whether the foreign matter is attached to the sheet or not on the basis of the captured image.

If the quality managing section 198d determines that no foreign matter is attached to the sheet, then the quality managing section 198d controls the unloading and loading robot 8 to deliver the workpiece 11 with the sheet fixed thereto into the cassette 6. Conversely, if the quality managing section 198d determines that the foreign matter is attached to the sheet, then the quality managing section 198d controls the unloading and loading robot 8 and the foreign matter removing unit 26 to remove the foreign matter from the sheet and thereafter determines again whether the foreign matter is attached to the sheet or not as described above.

If the decision is changed on the basis of the captured image, i.e., if it is determined that no foreign matter is attached to the sheet, then the quality managing section 198d controls the unloading and loading robot 8 to deliver the workpiece 11 with the sheet fixed thereto into the cassette 6. Conversely, if the decision is not changed on the basis of the captured image, i.e., if it is determined that the foreign matter is attached to the sheet, then the quality managing section 198d controls the unloading and loading robot 8, the image capturing unit 19, and the foreign matter removing unit 26 to repeat the removal of the foreign matter from the sheet and the determination as to whether the foreign matter is attached to the sheet or not alternately a predetermined number of times.

In a case where the removal of the foreign matter from the sheet by the foreign matter removing unit 26 is repeated in a plurality of cycles, operating conditions for the foreign matter removing unit 26 may be changed in each cycle. Specifically, operating conditions in a succeeding cycle, e.g., the flow rate and/or the pressure of the fluid ejected from the nozzle 34a of the fluid ejecting mechanism 34, may be set to a value or values for better removal of the foreign matter from the sheet, e.g., to a higher level or levels, than operating conditions in a preceding cycle.

If the decision is changed during one of the repeated cycles, then the quality managing section 198d controls the unloading and loading robot 8 to deliver the workpiece 11 with the sheet fixed thereto into the cassette 6. Conversely, if the repeated cycles are completed without a change in the decision, then the quality managing section 198d controls the touch panel on the outer side surface of the housing 184 to report to the operator that the workpiece 11 with the sheet fixed thereto is inadequate for being processed subsequently and controls the unloading and loading robot 8 to deliver the workpiece 11 with the sheet fixed thereto into the cassette 6.

Moreover, the quality managing section 198d controls the fan unit 188 to establish a suitable level of cleanliness in the housing 184 for providing a workpiece 11 with a sheet fixed thereto that is adequate for being processed subsequently, or stated otherwise, for processing a workpiece 11 after it is unloaded from the removing unit 126 until it is delivered into the cassette 6.

### <(11) Modification>

The details described above represent an aspect of the present invention. The present invention is not limited to the disclosure detailed above. According to the present invention, for example, the sheet fixed to the face side 11a of the workpiece 11 may not contain an adhesive layer. In the absence of an adhesive layer, the sheet is fixed to the face side 11a of the workpiece 11 by a thermocompression bonding process. In the thermocompression bonding process, the roller 114 of the pressing unit 112 incorporates a heater therein, and the fixing unit 102 is operated as described above while the heater is heating the roller 114.

The structural and methodical details according to the above embodiments may be changed or modified without departing from the scope of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A sheet fixing apparatus for fixing to a target surface of a workpiece a sheet that is commensurate in shape with the target surface, comprising:
an image capturing unit having a first camera for capturing images of the target surface before the sheet is fixed thereto; and
a controller for controlling the image capturing unit, wherein
the controller determines whether foreign matter is attached to the target surface or not on a basis of a first image captured of the target surface by the first camera by controlling the image capturing unit to capture the first image before the sheet is fixed to the target surface.

2. The sheet fixing apparatus according to claim 1, further comprising:
a foreign matter removing unit for removing foreign matter from the target surface, wherein
the controller controls the foreign matter removing unit to remove foreign matter from the target surface if the controller determines that the foreign matter is attached to the target surface.

3. The sheet fixing apparatus according to claim 1, wherein
the image capturing unit further has a second camera for capturing images of the sheet after the sheet has been fixed to the target surface, and
the controller determines whether foreign matter is attached to the sheet or not on a basis of a second image captured of the sheet by the second camera by controlling the image capturing unit to capture the second image after the sheet has been fixed to the target surface.

4. The sheet fixing apparatus according to claim 3, further comprising:
a foreign matter removing unit for removing foreign matter from the target surface and/or the sheet, wherein
the controller controls the foreign matter removing unit to remove foreign matter from the target surface if the controller determines that the foreign matter is attached to the target surface, and controls the foreign matter removing unit to remove foreign matter from the sheet if the controller determines that the foreign matter is attached to the sheet.

5. The sheet fixing apparatus according to claim 1, wherein
the first camera is capable of capturing images of the sheet after the sheet has been fixed to the target surface, and
the controller determines whether foreign matter is attached to the sheet or not on a basis of a second image captured of the sheet by the first camera by controlling the image capturing unit to capture the second image after the sheet has been fixed to the target surface.

6. The sheet fixing apparatus according to claim 5, further comprising:
a foreign matter removing unit for removing foreign matter from the target surface and/or the sheet, wherein
the controller controls the foreign matter removing unit to remove foreign matter from the target surface if the controller determines that the foreign matter is attached to the target surface, and controls the foreign matter removing unit to remove foreign matter from the sheet if the controller determines that the foreign matter is attached to the sheet.

7. The sheet fixing apparatus according to claim 1, wherein
the workpiece includes a wafer having a notch or an orientation flat defined in an outer edge thereof, and
the controller specifies a position of the notch or the orientation flat on a basis of a third image captured of the target surface by the first camera by controlling the image capturing unit to capture the third image before the sheet is fixed to the target surface while the workpiece is being irradiated with light applied to a side of the workpiece that is opposite the target surface.

8. The sheet fixing apparatus according to claim 7, further comprising:
a cassette table supporting thereon a cassette with the workpiece housed therein; and
an unloading and loading robot for unloading the workpiece from the cassette supported on the cassette table before the sheet is attached to the target surface and/or loading the workpiece into the cassette supported on the cassette table after the sheet has been attached to the target surface, the unloading and loading robot including a holding unit for holding the workpiece and a light emitter for irradiating the workpiece held by the holding unit with light, wherein
the controller controls the image capturing unit to capture the third image of the target surface before the sheet is fixed to the target surface while controlling the unloading and loading robot to cause the holding unit to hold the workpiece with the target surface being exposed and to cause the light emitter to irradiate the workpiece with light applied to the side of the workpiece that is opposite the target surface.

9. The sheet fixing apparatus according to claim 1, further comprising:
a preparing unit for preparing an individual sheet including a to-be-fixed region that is of a shape commensurate with the target surface and an excess region surrounding the to-be-fixed region;
a fixing unit for fixing the to-be-fixed region of the individual sheet prepared by the preparing unit to the target surface of the workpiece; and
a removing unit for removing the excess region from the individual sheet after the to-be-fixed region has been fixed to the target surface by the fixing unit, wherein
the fixing unit includes
a first holding unit for holding the workpiece,
a second holding unit for holding the individual sheet, and
a pressing unit for pressing the to-be-fixed region of the individual sheet against the target surface of the workpiece, and
the controller controls the fixing unit to cause the pressing unit to press the to-be-fixed region against the target surface while the first holding unit is holding the workpiece with the target surface being exposed and the second holding unit is holding the individual sheet with the to-be-fixed region being exposed and facing the target surface.

10. The sheet fixing apparatus according to claim 9, wherein
the pressing unit includes a roller positioned to grip the individual sheet held by the second holding unit in coaction with the workpiece held by the first holding unit, and
the controller controls the pressing unit to cause the roller to roll, thereby pressing the to-be-fixed region against the target surface.

11. The sheet fixing apparatus according to claim 10, wherein
the fixing unit further includes
a depressurizing unit for depressurizing a space to a pressure lower than an atmospheric pressure when the to-be-fixed region is fixed to the target surface in the space,
the depressurizing unit includes
a chamber for accommodating therein the first holding unit for holding the workpiece, the second holding unit for holding the individual sheet, and the roller, and
a pump for depressurizing an internal space in the chamber, and
the controller controls the pressing unit and the depressurizing unit to press the to-be-fixed region against the target surface while the pump is depressurizing the internal space in the chamber.

12. The sheet fixing apparatus according to claim 9, further comprising:
a housing that houses therein the preparing unit, the fixing unit, and the removing unit;
a fan for developing a downflow of air in the housing; and
a counter for counting fine particles in the housing, wherein
the controller controls the fan to change operating conditions depending on the number of fine particles counted by the counter.

13. A method of manufacturing a combination of a workpiece and a sheet fixed to a target surface of the workpiece, the sheet being commensurate in shape with the target surface, comprising:
fixing the sheet to the workpiece after it has been determined that no foreign matter is attached to the target surface on a basis of a first image captured of the target surface.
